(19) United States
(12) Patent Application Publication
(10) Pub. No.: US 2014/0360546 A1
(43) Pub. Date: Dec. 11, 2014

(54) SILICON-BASED THERMOELECTRIC MATERIALS INCLUDING ISOELECTRONIC IMPURITIES, THERMOELECTRIC DEVICES BASED ON SUCH MATERIALS, AND METHODS OF MAKING AND USING SAME

(71) Applicant: Alphabet Energy, Inc., Hayward, CA (US)

(72) Inventors: John REIFENBERG, Pleasanton, CA (US); Lindsay MILLER, Berkeley, CA (US); Matthew L. SCULLIN, San Francisco, CA (US)

(21) Appl. No.: 14/297,444

(22) Filed: Jun. 5, 2014

Related U.S. Application Data
(60) Provisional application No. 61/832,781, filed on Jun. 8, 2013.

(51) Int. Cl. H01L 35/22; H01L 35/34

(52) U.S. Cl. CPC H01L 35/22; H01L 35/34
USPC 136/201; 136/239; 136/205; 252/62.3 T; 438/54

(57) ABSTRACT

Silicon-based thermoelectric materials including isoelectronic impurities, thermoelectric devices based on such materials, and methods of making and using same are provided. According to one embodiment, a thermoelectric material includes silicon and one or more isoelectronic impurity atoms selected from the group consisting of carbon, tin, and lead disposed within the silicon in an amount sufficient to scatter thermal phonons propagating through the silicon and below a saturation limit of the one or more isoelectronic impurity atoms in the silicon. In one example, the thermoelectric material also includes germanium atoms disposed within the silicon in an amount sufficient to scatter thermal phonons propagating through the silicon and below a saturation limit of germanium in the silicon. Each of the one or more isoelectronic impurity atoms and the germanium atoms can independently substitute for a silicon atom or can be disposed within an interstice of the silicon.

### CROSS-REFERENCE TO RELATED APPLICATIONS

This application claims priority to U.S. Provisional Patent Application No. 61/832,781, filed Jun. 8, 2013, the entire contents of which are incorporated by reference herein for all purposes.

### BACKGROUND

The present invention is related to silicon-based thermoelectric materials. More particularly, the invention provides silicon-based thermoelectric materials that include isoelectronic impurities, according to certain embodiments. Merely by way of example, the invention has been applied to thermoelectric devices based on such materials, and methods of making and using such materials or such devices. However, it would be recognized that the invention has a much broader range of applicability.

Silicon is a well known semiconductor and many established processing techniques for traditional applications of silicon in electronics may also be applicable to enhance thermoelectric performance. For example, FIG. 1A is a simplified diagram illustrating prior art silicon. It can be seen that the silicon (Si) atoms are arranged in a substantially homogeneous, periodic lattice. As is known in the art, silicon has a diamond cubic structure with substantially no grain boundaries disposed within the lattice. The crystalline structure of the silicon atoms can extend over any suitable length scale. For example, single-crystal silicon wafers having diameters of several inches have been produced. However, such wafers can have relatively poor thermoelectric properties.

Alternatively, for example, nanostructured semiconductor materials have been shown to have relatively good thermoelectric properties for making high performance thermoelectric devices. The nanostructure of such materials can disrupt the crystalline structure of silicon atoms in a manner that can improve the thermoelectric properties of the material. Combining nanostructure processing with other semiconductor processing is one of the many options that can lead to high-performance thermoelectric devices. For example, silicon nanowires, nanoholes, nanomesh, and the like have been formed in thin silicon-on-insulator epitaxial layers or as arrays of nanowires, and can result in nanoscale structures such as thin films that are relatively small in physical size. Such structures can be thin films and can resemble ribbons, for instance, that have been shown to be microns wide and microns long, tens to hundreds of nanometers thick, with 1-100 nm diameter holes within. These structures demonstrate the fundamental ability of closely packed nanostructures to affect phonon thermal transport by reducing thermal conductivity while not affecting electrical properties greatly. The thermoelectric properties of a material can be expressed as the thermoelectric figure-of-merit ZT, given by ZT=S²σ/k, where S is the Seebeck coefficient representing the material's thermopower, σ the electrical conductivity, and k the thermal conductivity. Nanostructured semiconductor materials have been shown to have relatively good figures of merit ZT for making high performance thermoelectric devices.

Another focus may be put on techniques that not only reduce the thermal conductivity, but also increase the Seebeck coefficient and/or increase the electrical conductivity of the resultant thermoelectric material. Utilizing advantage of nanostructured features within the silicon base material with reduced thermal conductivity can be applied to transform a micron scaled cluster of nanostructured materials into a bulk sized material suitable for practical power generation, where a temperature gradient is applied to the thermoelectric material and the Seebeck effect is employed to drive a gradient in voltage and in turn the flow of electrical current. Additionally, making bulk sized silicon base material bearing nanostructure features can enhance thermoelectric performance.

Hence, it is highly desirable to create thermoelectric materials having improved properties.

### SUMMARY

The present invention is related to silicon-based thermoelectric materials. More particularly, the invention provides silicon-based thermoelectric materials that include isoelectronic impurities, according to certain embodiments. Merely by way of example, the invention has been applied to thermoelectric devices based on such materials, and methods of making and using such materials or such devices. However, it would be recognized that the invention has a much broader range of applicability.

According to one embodiment, a thermoelectric material includes silicon; and one or more isoelectronic impurity atoms selected from the group consisting of carbon, tin, and lead disposed within the silicon in an amount sufficient to scatter thermal phonons propagating through the silicon and below a saturation limit of the one or more isoelectronic impurity atoms in the silicon.

In one example, the thermoelectric material includes germanium atoms disposed within the silicon in an amount sufficient to scatter thermal phonons propagating through the silicon and below a saturation limit of germanium in the silicon. In another example, each of the one or more isoelectronic impurity atoms and the germanium atoms independently substitutes for a silicon atom or is disposed within an interstice of the silicon. In another example, the silicon, the one or more isoelectronic impurity atoms, and the germanium atoms define a single phase of the thermoelectric material. In another example, the thermoelectric material further includes an N or P type dopant disposed within the silicon. In another example, the thermoelectric material consists essentially of the silicon, the one or more isoelectronic impurity atoms, the germanium atoms, and the N or P type dopant. In another example, the amount of the germanium atoms is approximately 0.001 atomic % to approximately 2 atomic %, and the amount of each of the one or more isoelectronic impurity atoms is approximately 0.001 atomic % to approximately 2 atomic %. In another example, the amount of each of the one or more isoelectronic impurity atoms is approximately 0.001 atomic % to approximately 2 atomic %. In another example, the one or more isoelectronic impurity atoms include tin and carbon. In another example, the one or more isoelectronic impurity atoms include tin and lead. In another example, the one or more isoelectronic impurity atoms include carbon and the material further includes germanium. In another example, the one or more isoelectronic impurity atoms include lead and the material further includes germanium. In yet another example, the one or more isoelectronic impurity atoms include tin and the material further includes germanium.

In another example, a nanocrystal, nanowire, or nanoribbon includes a thermoelectric material includes silicon; and one or more isoelectronic impurity atoms disposed within the silicon in an amount sufficient to scatter thermal phonons propagating through the silicon and below a saturation limit of the one or more isoelectronic impurity atoms in the silicon.

According to another embodiment, a device for thermoelectric conversion includes a first electrode; a second electrode; and a thermoelectric material disposed between the first electrode and the second electrode. The thermoelectric material includes silicon; and one or more isoelectronic impurity atoms selected from the group consisting of carbon, tin, and lead disposed within the silicon in an amount sufficient to scatter thermal phonons propagating through the silicon and below a saturation limit of the one or more isoelectronic impurity atoms in the silicon.

In another example, the thermoelectric material further includes germanium atoms disposed within the silicon in an amount sufficient to scatter thermal phonons propagating through the silicon and below a saturation limit of germanium in the silicon.

In another example, each of the one or more isoelectronic impurity atoms and the germanium atoms independently substitutes for a silicon atom in the silicon or is disposed within an interstice of the silicon. In another example, the silicon, the one or more isoelectronic impurity atoms, and the germanium atoms define a single phase of the thermoelectric material. In another example, the thermoelectric material further includes an N or P type dopant disposed within the silicon. In another example, the thermoelectric material consists essentially of the silicon, the one or more isoelectronic impurity atoms, the germanium atoms, and the N or P type dopant. In another example, the amount of the germanium atoms is approximately 0.001 atomic % to approximately 2 atomic %, and the amount of each of the one or more isoelectronic impurity atoms is approximately 0.001 atomic % to approximately 2 atomic %. In another example, the amount of each of the one or more isoelectronic impurity atoms is approximately 0.001 atomic % to approximately 2 atomic %. In another example, the device is configured to generate an electric current flowing between the first electrode and the second electrode through the thermoelectric material based on the first and second electrodes being at different temperatures than one another. In another example, the one or more isoelectronic impurity atoms include tin and carbon. In another example, the one or more isoelectronic impurity atoms include tin and lead. In another example, the one or more isoelectronic impurity atoms include carbon and the material further includes germanium. In another example, the one or more isoelectronic impurity atoms include lead and the material further includes germanium. In yet another example, the one or more isoelectronic impurity atoms include tin and the material further includes germanium.

According to yet another embodiment, a method of making a thermoelectric material includes providing silicon; and disposing one or more isoelectronic impurity atoms selected from the group consisting of carbon, tin, and lead within the silicon in an amount sufficient to scatter thermal phonons propagating through the silicon and below a saturation limit of the one or more isoelectronic impurity atoms in the silicon.

In another example, the method includes disposing germanium atoms within the silicon in an amount sufficient to scatter thermal phonons propagating through the silicon and below a saturation limit of germanium in the silicon. In yet another example, the silicon, the one or more isoelectronic impurity atoms, and the germanium atoms define a single phase of the thermoelectric material. In another example, the method includes independently substituting each of the one or more isoelectronic impurity atoms and the germanium atoms for a silicon atom in the silicon or disposing that isoelectronic impurity atom or germanium atom within an interstice of the silicon. In another example, the silicon, the one or more isoelectronic impurity atoms, and the germanium atoms define a single phase of the thermoelectric material. In another example, the method further includes disposing an N or P type dopant within the silicon. In another example, the thermoelectric material consists essentially of the silicon, the one or more isoelectronic impurity atoms, the germanium atoms, and the N or P type dopant. In another example, the amount of the germanium atoms is approximately 0.001 atomic % to approximately 2 atomic %, and the amount of each of the one or more isoelectronic impurity atoms is approximately 0.001 atomic % to approximately 2 atomic %. In another example, the amount of each of the one or more isoelectronic impurity atoms is approximately 0.001 atomic % to approximately 2 atomic %. In yet another example, disposing the one or more isoelectronic impurity atoms within the silicon includes disposing the silicon within a diffusion furnace; and diffusing the one or more isoelectronic impurity atoms into the silicon within the diffusion furnace. In yet another example, disposing the one or more isoelectronic impurity atoms within the silicon includes obtaining a powdered mixture of silicon and the one or more isoelectronic impurity; and sintering the powdered mixture to form the silicon having the one or more isoelectronic impurity atoms disposed therein. In yet another example, disposing the one or more isoelectronic impurity atoms within the silicon includes obtaining a melt of silicon and the one or more isoelectronic impurity; and solidifying the melt to form the silicon having the one or more isoelectronic impurity atoms disposed therein. In yet another example, the one or more isoelectronic impurity atoms include tin and carbon. In another example, the one or more isoelectronic impurity atoms include tin and lead. In another example, the one or more isoelectronic impurity atoms include carbon and the material further includes germanium. In another example, the one or more isoelectronic impurity atoms include lead and the material further includes germanium. In yet another example, the one or more isoelectronic impurity atoms include tin and the material further includes germanium.

According to yet another embodiment, a method of making a thermoelectric device includes providing a thermoelectric material, and disposing the thermoelectric material between a first electrode and a second electrode. The thermoelectric material includes silicon; and one or more isoelectronic impurity atoms selected from the group consisting of carbon, tin, and lead disposed within the silicon in an amount sufficient to scatter thermal phonons propagating through the silicon and below a saturation limit of the one or more isoelectronic impurity atoms in the silicon. In another example, the thermoelectric material further includes germanium atoms disposed within the silicon in an amount sufficient to scatter thermal phonons propagating through the silicon and below a saturation limit of germanium in the silicon.

In yet another example, the silicon, the one or more isoelectronic impurity atoms, and the germanium atoms define a single phase of the thermoelectric material. In another example, each of the one or more isoelectronic impurity atoms and the germanium atoms independently substitutes for a silicon atom in the silicon or is disposed within an interstice of the silicon. In another example, the silicon, the one or more isoelectronic impurity atoms, and the germanium atoms define a single phase of the thermoelectric material. In another example, the thermoelectric material further includes an N or P type dopant disposed within the silicon. In another example, the thermoelectric material consists essentially of the silicon, the one or more isoelectronic impurity atoms, the germanium atoms, and the N or P type dopant. In another example, the amount of the germanium atoms is approximately 0.001 atomic % to approximately 2 atomic %, and the amount of each of the one or more isoelectronic impurity atoms is approximately 0.001 atomic % to approximately 2 atomic %. In another example, the amount of each of the one or more isoelectronic impurity atoms is approximately 0.001 atomic % to approximately 2 atomic %. In another example, the one or more isoelectronic impurity atoms include tin and carbon. In another example, the one or more isoelectronic impurity atoms include tin and lead. In another example, the one or more isoelectronic impurity atoms include carbon and the material further includes germanium. In another example, the one or more isoelectronic impurity atoms include lead and the material further includes germanium. In yet another example, the one or more isoelectronic impurity atoms include tin and the material further includes germanium.

According to yet another embodiment, a method of using a thermoelectric device includes providing a thermoelectric device; and generating an electric current flowing between the first electrode and the second electrode through the thermoelectric material based on the first and second electrodes being at different temperatures than one another. The thermoelectric material includes silicon; and one or more isoelectronic impurity atoms selected from the group consisting of carbon, tin, and lead disposed within the silicon in an amount sufficient to scatter thermal phonons propagating through the silicon and below a saturation limit of the one or more isoelectronic impurity atoms in the silicon.

According to still another embodiment, a method of using a thermoelectric device includes providing a thermoelectric device; and pumping heat from the first electrode to the second electrode through the thermoelectric material responsive to an electrical current. The thermoelectric material includes silicon; and one or more isoelectronic impurity atoms selected from the group consisting of carbon, tin, and lead disposed within the silicon in an amount sufficient to scatter thermal phonons propagating through the silicon and below a saturation limit of the one or more isoelectronic impurity atoms in the silicon.

Depending on the embodiment, one or more benefits may be achieved. These benefits and various additional objects, features, and advantages of the present application can be fully appreciated with reference to the detailed description and accompanying drawings that follow.

### BRIEF DESCRIPTION OF DRAWINGS

FIG. 1A is a simplified diagram illustrating prior art silicon.

FIG. 1B is a simplified diagram illustrating an exemplary silicon-based thermoelectric material including silicon and an isoelectronic impurity, according to certain embodiments of the present invention.

FIG. 1C is a simplified diagram illustrating an exemplary silicon-based thermoelectric material including silicon and a plurality of isoelectronic impurities, according to certain embodiments of the present invention.

FIG. 2A is a simplified diagram illustrating an exemplary thermoelectric device including a silicon-based thermoelectric material including silicon and one or more isoelectronic impurities, according to certain embodiments of the present invention.

FIG. 2B is a simplified diagram illustrating an exemplary alternative thermoelectric device including a silicon-based thermoelectric material including silicon and one or more isoelectronic impurities, according to certain embodiments of the present invention.

FIG. 2C is a simplified diagram illustrating another exemplary alternative thermoelectric device including a silicon-based thermoelectric material including silicon and one or more isoelectronic impurities, according to certain embodiments of the present invention.

FIG. 3 is a simplified diagram illustrating an exemplary effect of concentration of an isoelectronic impurity on thermal conductivity of a silicon-based thermoelectric material, according to certain embodiments of the present invention.

FIG. 4 is a simplified diagram illustrating an exemplary effect of concentration of an isoelectronic impurity on electrical conductivity of a silicon-based thermoelectric material, according to certain embodiments of the present invention.

FIG. 5 is a simplified diagram illustrating an exemplary effect of concentration of an isoelectronic impurity on the Seebeck coefficient of a silicon-based thermoelectric material, according to certain embodiments of the present invention.

FIG. 6 is a simplified diagram illustrating an exemplary method for making and using a thermoelectric device including a silicon-based thermoelectric material including silicon and one or more isoelectronic impurities, according to certain embodiments of the present invention.

FIG. 7 is a simplified diagram illustrating an exemplary method for preparing a silicon-based thermoelectric material including silicon and one or more isoelectronic impurities, according to certain embodiments of the present invention.

FIGS. 8A-8F are simplified diagrams respectively illustrating exemplary methods for introducing one or more isoelectronic impurities into silicon, according to certain embodiments of the present invention.

FIG. 9 is a simplified diagram illustrating an exemplary apparatus that can be used to introduce one or more isoelectronic impurities into silicon, according to certain embodiments of the present invention.

FIG. 10 is a simplified diagram illustrating the measured electrical resistivity ρ (μΩm) of exemplary silicon-based thermoelectric materials including silicon and different amounts and types of isoelectronic impurities and a P type dopant as a function of amount of tin therein, according to certain embodiments of the present invention.

FIG. 11 is a simplified diagram illustrating the measured thermal conductivity k (W/mK) of exemplary silicon-based thermoelectric materials including silicon and different amounts and types of isoelectronic impurities and a P type dopant as a function of amount of tin therein, according to certain embodiments of the present invention.

FIG. 12 is a simplified diagram illustrating the measured Seebeck coefficient S (μV/K) of exemplary silicon-based thermoelectric materials including silicon and different amounts and types of isoelectronic impurities and a P type dopant as a function of amount of tin therein, according to certain embodiments of the present invention.

FIG. 13 is a simplified diagram illustrating the reciprocal 1/kρ (K/(WμΩ)) of the product kρ of the measured thermal conductivity k and electrical resistivity ρ of exemplary silicon-based thermoelectric materials including silicon and different amounts and types of isoelectronic impurities and a P type dopant as a function of amount of tin therein, according to certain embodiments of the present invention.

### DETAILED DESCRIPTION

The present invention is related to silicon-based thermoelectric materials. More particularly, the invention provides silicon-based thermoelectric materials that include isoelectronic impurities, according to certain embodiments. Merely by way of example, the invention has been applied to thermoelectric devices based on such materials, and methods of making and using such materials or such devices. However, it would be recognized that the invention has a much broader range of applicability.

For example, in one or more embodiments of the present invention, the thermoelectric figure of merit ZT of silicon-based thermoelectric materials is improved by introducing one or more isoelectronic impurities so as to reduce the thermal conductivity, and/or increase the Seebeck coefficient, and/or increase the electrical conductivity of the resultant material. The thermoelectric material can include silicon, and atoms of the one or more isoelectronic impurities disposed within the silicon. By “isoelectronic” it is meant an element that has an analogous valence electron configuration as does silicon. For example, the valence electron configuration of silicon is 3S² 3P², and the standard atomic weight of silicon (Si) is 28. Isotopes of Si²⁸, such as Si²⁹, Si³⁰, Si³², and Si⁴² (also referred to as Si^{28+x}) also have a 3S² 3P² valence electron configuration, but have different masses or different radii, or both, than does Si²⁸. Or, for example, other group IVB (also referred to as group 14) elements can have an analogous valence electron configuration as does silicon. For example, carbon (C) has a 2s² 2p² valence electron configuration, which can be considered to be analogous to that of silicon because the 2p² electrons of carbon can be expected to behave analogously to the 3p² electrons of silicon in at least some respects when carbon atoms are disposed within silicon. Or, for example, germanium (Ge) has a 3d¹⁰ 4s² 4p² valence electron configuration, which can be considered to be analogous to that of silicon because the 4p² electrons of germanium can be expected to behave analogously to the 3p² electrons of silicon in at least some respects when germanium atoms are disposed within silicon. Or, for example, tin (Sn) has a 4d¹⁰ 5s² 5p² valence electron configuration, which can be considered to be analogous to that of silicon because the 5p² electrons of tin can be expected to behave analogously to the 3p² electrons of silicon in at least some respects when tin atoms are disposed within silicon. Or, for example, lead (Pb) has a 4f¹⁴ 5d¹⁰ 6s² 6p² valence electron configuration, which can be considered to be analogous to that of silicon because the 4p² electrons of lead can be expected to behave analogously to the 3p² electrons of silicon in at least some respects when lead atoms are disposed within silicon.

Each of the one or more isoelectronic impurities can be in an amount sufficient to scatter thermal phonons propagating through the silicon. Without wishing to be bound by any theory, it is believed that a difference in a physical property, e.g., mass or radius, or both, of the atoms of the one or more isoelectronic impurities as compared to that physical property of the atoms of the silicon can define scattering centers that can inhibit the free propagation of certain thermal phonons through the silicon. For example, the impurities can induce localized strain or density changes in the silicon that cause scattering of thermal phonons. Without wishing to be bound by any theory, it is believed that such scattering can reduce the thermal conductivity of the material by inhibiting the flow of heat through the material that otherwise would be carried by those thermal phonons. The one or more isoelectronic impurities need not necessarily scatter all thermal phonons, but instead can scatter a sufficient number and frequency distribution of thermal phonons as to measurably reduce the thermal conductivity of the thermoelectric material. For example, the isoelectronic impurities can act as point scatterers for phonons having relatively short wavelengths, e.g., wavelengths less than 200 nm, and having relatively high energies. Additionally, or alternatively, the distribution of the isoelectronic impurities throughout the silicon can lead to coherent scattering of longer wavelength phonons. It should be appreciated that the mechanism for improving the thermoelectric properties of the material need not necessarily be limited to, or even include, reducing the thermal conductivity of the material or scattering thermal phonons. For example, the one or more isoelectronic impurities can improve the thermoelectric properties of the material—e.g., by increasing the figure of merit ZT of the material—by changing the electrical properties of the material in addition to, or instead, of changing the thermal properties of the material. For example, the one or more isoelectronic impurities can increase the Seebeck coefficient of the material or increase the electrical conductivity of the material, or both.

Additionally, the one or more isoelectronic impurities can be present in an amount that is below a saturation limit of each such impurity in the silicon. For example, the atoms of the one or more isoelectronic impurities can be substantially homogeneously distributed throughout and incorporated within the silicon in a manner that generally maintains the structure of the silicon and provides a single-phase material. The atoms of the one or more isoelectronic impurities can, for example, substitute for corresponding silicon atoms or be disposed within interstices of the silicon, or a combination thereof. The material can be, but need not necessarily be, at least partially crystalline. For example, the material can include a plurality of unit cells, each of which can be generally crystalline, e.g., have a diamond cubic structure. However, not all of the unit cells need be oriented in the same direction as one another, although in certain embodiments some or all of the unit cells can be oriented in the same direction as one another. That is, the length scale over which the material is crystalline suitably can be selected so as to provide desirable thermoelectric properties. The atoms of the one or more isoelectronic impurities can cause unit cells of the silicon to have a relatively different shape or size than other cells of the silicon that lack such impurities, but substantially maintain the general crystal structure of that unit cell. Without wishing to be bound by any theory, it is believed that the changes to the unit cells caused by the atoms of the one or more isoelectronic impurities can induce local strain or local density changes, or both, to the silicon that can scatter thermal phonons or otherwise improve the thermoelectric properties of the material. In comparison, if the amount of the one or more isoelectronic impurities instead were increased to above their respective saturation limits in silicon, then the impurities either can be expected to precipitate out of the silicon so as to form phase-separated domains located within the silicon, or can be expected to form an alloy with the silicon that has a crystal structure that is significantly different than that of silicon alone.

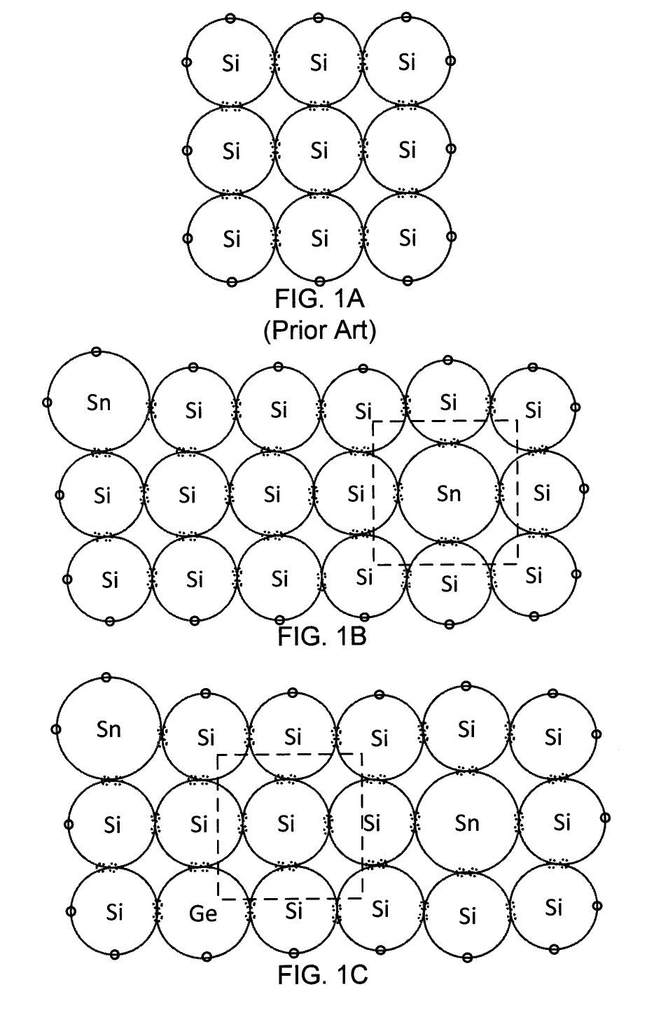

For example, in some embodiments of the present invention, a single isoelectronic impurity can be included within the silicon. FIG. 1B is a simplified diagram illustrating an exemplary silicon-based thermoelectric material including silicon and an isoelectronic impurity, according to certain embodiments of the present invention. For example, isoelectronic impurities such as germanium (Ge), Si²⁹, or Si³² have been shown through experimental data (SiGe) and calculations (Si²⁹, Si³²) to increase the thermoelectric figure of merit in silicon-based thermoelectric materials. Another suitable isoelectronic impurity is tin (Sn). Without wishing to be bound by any theory, it is believed that a primary mechanism is through reduction of the thermal conductivity. In some cases, the magnitude of the Seebeck coefficient and electrical conductivity can increase as well. In a specific embodiment, the elements Sn and Pb, which are also isoelectronic with Si and can cause reduction of the thermal conductivity when they are mixed with Si, can be added into the present silicon-based thermoelectric material for improving its thermoelectric performance to an even greater extent. The thermal conductivity of the Si—Sn or Si—Pb mixture can be expected to be even lower than those of Si—Ge and Si—Si^{28+x} systems because the Sn and Pb atoms have greater atomic mass and strain the material more than Ge and Si^{28+x}. Alternatively, the element C has a lower atomic mass than Si, and also can be expected to induce strain in the Si based material.

In another specific embodiment, Sn is selected as an additive isoelectronic element because of its non-toxicity, relatively large atomic mass and radius, and relatively high solubility in Si at temperatures (<1200° C.) that can be used in standard Si processes. These standard Si processes include silicon ingot formation process, wafer process, doping/ion-implantation processes of other material treatment processes, etching process to form silicon nanostructures including nanowires/nanoholes/nanotubes/nanoribbons, process for collecting silicon nano-powders. Adding one or a combination of Sn, Pb, C, Ge, or other isoelectronic impurities into silicon material in any forms including Si nanowires, mesoporous Si, Si inverse opal, and sintered bulk size nanostructured Si material can be carried during or after the above-mentioned Si processes to fabricate the high-performance Si-based thermoelectric material. The Si based material optionally can also be doped with standard N type (e.g., P, As, Sb, Bi) or P type (e.g., B, Al, Ga, In) dopants to improve the thermoelectric figure of merit or otherwise provide desired thermal or electrical properties.

In the embodiment illustrated in FIG. 1B, the isoelectronic impurity is tin (Sn), but it should be understood that any suitable isoelectronic impurity alternatively can be included, such as carbon (C), or lead (Pb). It can be seen in FIG. 1B that atoms of the isoelectronic impurity, e.g., tin (Sn), can be substantially homogeneously distributed throughout the silicon so as to create localized modifications to the structure of the material. Although it is suggested in FIG. 1B that the material has a substantially homogeneous, periodic lattice, it should be understood that the material need not necessarily be crystalline at all, e.g., can be amorphous, or can be crystalline on any desired length scale. For example, although a given unit cell of the material such as suggested by the dashed box in FIG. 1B can be generally crystalline, different unit cells need not necessarily be oriented in the same direction as one another. For example, the material can be generally crystalline on a length scale of approximately 2 nm or less, or approximately 5 nm or less, or approximately 10 nm or less, or approximately 20 nm or less, or approximately 50 nm or less, or approximately 100 nm or less, but need not necessarily be crystalline above that length scale. The isoelectronic impurity atoms, e.g., tin, can be in an amount sufficient to scatter thermal phonons propagating through the silicon and below a saturation limit of the isoelectronic impurity atoms, e.g., tin, in the silicon. For example, each of the isoelectronic impurity atoms, e.g., tin, independently can substitute for a silicon atom in the silicon or can be disposed within an interstice of the silicon. For example, the silicon and the isoelectronic impurity atoms, e.g., tin, can define a single phase of the thermoelectric material. A lack of long-range crystallinity of the thermoelectric material can further improve the thermoelectric materials of the property. In one illustrative embodiment, the material can be based on sintered silicon nanowires prepared in a manner analogous to that described in US Patent Publication No. 2014/0116491 to Reifenberg et al., the entire contents of which are incorporated herein by reference.

Optionally, the thermoelectric material illustrated in FIG. 1B further can include an N or P type dopant. In such embodiments, the thermoelectric material can consist essentially of the silicon, the atoms of the isoelectronic impurity, e.g., tin, and the N or P type dopant. Exemplary N type dopants include group VB (also referred to as group 15) elements such as phosphorous (P), arsenic (As), antimony (Sb), and the like. Exemplary P type dopants include group IIIB (also referred to as group 13) elements such as boron (B), aluminum (Al), gallium (Ga), and the like. In one example, the N or P type dopant can be in an amount between about 1E17/cm³ and 1E21/cm³. For example, the N or P type dopant can be in an amount between about 5E18/cm³ and 5E20/cm³.

As noted above, certain isoelectronic impurities can have an analogous valence electron configuration as does silicon, but a different mass or radius, or both. For example, tin has a relatively large covalent radius of approximately 1.40 Å as compared to the covalent radius of silicon, which is approximately 1.14 Å. As used herein, the terms “approximately” and “about” are intended to mean within 10% of the stated value unless otherwise noted. As illustrated in FIG. 1B, interspersing the tin atoms throughout the silicon (which also can be referred to as the silicon base material) can cause a distortion, e.g., expansion of the unit cells that include those tin atoms. Such distortion also can cause somewhat smaller distortions to other unit cells, e.g., adjacent unit cells, that do not include those tin atoms (these other unit cells need not necessarily have the same orientation as the unit cells that include the tin). Without wishing to be bound by any theory, it is believed that Sn atoms tend to take Si atom vacancy to become substitution atoms rather than as interstitial atoms, although it will be appreciated that Sn also can be disposed within interstices of the silicon. In the exemplary embodiment illustrated in FIG. 1B, the Sn atoms replace a respective original Si atom as a substitution impurity. Without wishing to be bound by any theory, it is believed that the relatively large covalent radius difference between Sn and Si can induce a relatively strong strain field around each Sn atom, causing phonon scattering and reducing thermal conductivity of the silicon. Other isoelectronic elements can have different covalent radii than Si, which can induce a relatively strong strain field around atoms of such elements, causing phonon scattering and reducing thermal conductivity of the silicon.

The amount of the isoelectronic impurity can be selected so as to provide a suitable improvement to the thermoelectric properties of the silicon-based material. For example, the amount of the impurity atoms, e.g., tin, can be approximately 0.001 atomic % to approximately 2 atomic %. For example, the amount of the impurity atoms, e.g., tin, can be approximately 0.01 atomic % to approximately 2 atomic %. For example, the amount of the impurity atoms, e.g., tin, can be approximately 0.05 atomic % to approximately 1.5 atomic %. For example, the amount of the impurity atoms, e.g., tin, can be approximately 0.1 atomic % to approximately 1 atomic %. For example, the amount of the impurity atoms, e.g., tin, can be approximately 0.5 atomic % to approximately 1 atomic %. Or, for example, the amount of the impurity atoms, e.g., tin, can be approximately 0.01 atomic % to approximately 0.5 atomic %. For example, the amount of the impurity atoms, e.g., tin, can be approximately 0.1 atomic % to approximately 0.5 atomic %. As is known in the art, the atomic number density of silicon is approximately 5E22 cm⁻³, and the atomic % of an impurity can be converted to units of cm⁻³ by multiplying the atomic % by 5E22 cm⁻³. For example, 2 atomic % tin corresponds to approximately 1E21 cm⁻³. The saturation limit of tin in pure silicon has been characterized in the literature as being approximately 5E19 cm⁻³, with error bars of 10% or greater, or up to 50%. For further details, see Olesinski et al., “The Si—Sn (Silicon-Tin) System,” Bulletin of Alloy Phase Diagrams 5(3): 273-276 (1984), the entire contents of which are incorporated by reference herein. However, note that the solubility of elements such as tin can be increased by incorporating additional elements such as B, C, or Ge that have a different covalent radius than tin. As such, the literature value of 5E19 cm³ does not necessarily represent an upper bound on how much tin can be incorporated into a given thermoelectric material. Other isoelectronic impurities, such as C or Pb, can have respective solubility limits which further may be affected by the presence of other elements. In some embodiments, the amount of the isoelectronic impurity exceeds the solubility limit of that impurity in the silicon. For example, without wishing to be bound by any theory, rather than atoms of the isoelectronic impurity being substantially evenly distributed throughout the silicon, it is believed that relatively small phase domains each having multiple atoms of the of the isoelectronic impurity can be distributed throughout the silicon, e.g., substantially evenly.

Additionally, more than one type of isoelectronic impurity can be included in silicon so as to provide a synergistically enhanced improvement of the material's thermoelectric properties. For example, FIG. 1C is a simplified diagram illustrating an exemplary silicon-based thermoelectric material including silicon and a plurality of isoelectronic impurities, according to certain embodiments of the present invention. In the embodiment illustrated in FIG. 1C, the isoelectronic impurities are tin (Sn) and germanium (Ge), but it should be understood that any combination of different isoelectronic impurities can be used, e.g., any suitable combination of Sn, Ge, Pb, and C.

It can be seen in the illustrative embodiment of FIG. 1C that atoms of the isoelectronic impurities, e.g., tin (Sn) and germanium (Ge), respectively can be substantially homogenously distributed throughout the silicon so as to create localized modifications to the structure of the material. Although it is suggested in FIG. 1C that the material has a substantially homogeneous, periodic lattice, it should be understood that the material need not necessarily be crystalline at all, e.g., can be amorphous, or can be crystalline on any desired length scale. For example, although a given unit cell of the material such as suggested by the dashed box in FIG. 1C can be generally crystalline, different unit cells need not necessarily be oriented in the same direction as one another. For example, the material can be generally crystalline on a length scale of approximately 2 nm or less, or approximately 5 nm or less, or approximately 10 nm or less, or approximately 20 nm or less, or approximately 50 nm or less, or approximately 100 nm or less, but need not necessarily be crystalline above that length scale. Each of the isoelectronic impurity atoms, e.g., tin and germanium, can be in an amount sufficient to scatter thermal phonons propagating through the silicon and below a respective saturation limit of the isoelectronic impurity atoms, e.g., tin and germanium, in the silicon. For example, each of the isoelectronic impurity atoms, e.g., tin or germanium, independently can substitute for a silicon atom or can be disposed within an interstice of the silicon. For example, the silicon and the isoelectronic impurity atoms, e.g., tin and germanium, can define a single phase of the thermoelectric material. A lack of long-range crystallinity of the thermoelectric material can further improve the thermoelectric materials of the property. In one illustrative embodiment, the material can be based on sintered silicon nanowires prepared in a manner analogous to that described in US Patent Publication No. 2014/0116491 to Reifenberg et al.

Optionally, the thermoelectric material illustrated in FIG. 1C further can include an N or P type dopant. In such embodiments, the thermoelectric material can consist essentially of the silicon, the atoms of the isoelectronic impurities, e.g., tin and germanium, and the N or P type dopant. Exemplary N type dopants include group VB (also referred to as group 15) elements such as phosphorous (P), arsenic (As), antimony (Sb), and the like. Exemplary P type dopants include group IIIB (also referred to as group 13) elements such as boron (B), aluminum (Al), gallium (Ga), and the like. In one example, the N or P type dopant can be in an amount between about 1E17/cm³ and 1E21/cm³. For example, the N or P type dopant can be in an amount between about 5E18/cm³ and 5E50/cm³.

As noted above, isoelectronic impurities can have an analogous valence electron configuration as does silicon, but a different mass or radius, or both. For example, germanium has a relatively large covalent radius of approximately 1.22 Å as compared to that of silicon, which is approximately 1.14 Å, and a relatively small covalent radius as compared to that of tin, which is approximately 1.40 Å. As illustrated in FIG. 1C, disposing the tin and germanium atoms within the silicon (which also can be referred to as the silicon base material) can cause distortions, e.g., expansions of the unit cells that include those impurity atoms, with the tin inducing a larger distortion than does the germanium. Without wishing to be bound by any theory, it is believed that because the different impurities, e.g., tin and germanium, have different physical characteristics than one another, such as mass or radii, or both, the different impurities can scatter different frequency distributions of thermal phonons than one another, thus synergistically reducing the thermal conductivity of the silicon. For example, the impurities can cause disruptions in the silicon structure, e.g., one or more disruptions in any periodicity that the silicon otherwise may have had, and phonon scattering events can result from nonlinear interactions of phonons with the resulting silicon structure. One exemplary scattering source can be a disruption in mass, bond length, strain, or periodicity, or a combination thereof, caused by insertion of a first isoelectronic impurity (e.g., Sn) into the Si structure, or bonding between the element and Si, or both. Another exemplary scattering source can be a disruption in mass, bond length, strain, or periodicity, or a combination thereof, caused by insertion of a second isoelectronic impurity (e.g., Ge) into the Si structure, or bonding between the element and Si, or both. Another exemplary scattering source is scattering from Si lattice periodicity disruptions caused by other phonons in the Si lattice (also referred to as Umklapp scattering). Without wishing to be bound by any theory, it is believed that incorporating sufficient amounts of two or more different types of isoelectronic impurities into silicon, e.g., Sn and Ge, an additional interaction between the impurities, e.g., Sn and Ge, may cause the strain fields of the two impurities to overlap with one another. The effect of such a strain field on phonon scattering can be expected to be synergistic (nonlinear) relative to an additive (linear) effect of the strain fields between silicon and the individual impurities, because scattering is nonlinear. Additionally, such expansion also can cause somewhat smaller distortions to other unit cells, e.g., adjacent unit cells, that do not include those impurity atoms (the other unit cells need not necessarily have the same orientation as the unit cells that include the impurity atoms). Other isoelectronic elements can have different covalent radii than Si, which can induce a relatively strong strain field around atoms of such elements, causing phonon scattering and reducing thermal conductivity of the silicon.

In the exemplary embodiment illustrated in FIG. 1C, the Sn and Ge atoms each replace a respective original Si atom as a substitution impurity. Without wishing to be bound by any theory, it is believed that the relatively large covalent radius differences between Sn and Si can induce a relatively strong strain field around each Sn atom, causing phonon scattering and reducing thermal conductivity. Additionally, it is believed that the relatively large covalent radius differences between Ge and Si can induce a relatively strong strain field around each Ge atom, causing phonon scattering and reducing thermal conductivity. Additionally, it is believed that the relatively large covalent radius differences between Sn and Ge can provide a further synergistic effect that causes an enhancement in phonon scattering and a further reduction in thermal conductivity as compared to what can be expected based on disposing Sn alone, or Ge alone, within the silicon.

The respective amounts of each isoelectronic impurity can be co-selected so as to provide a suitable improvement to the thermoelectric properties of the silicon-based material. For example, the amount of the first impurity atoms, e.g., tin, can be approximately 0.001 atomic % to approximately 2 atomic %. For example, the amount of first impurity atoms, e.g., tin, can be approximately 0.01 atomic % to approximately 2 atomic %. For example, the amount of the first impurity atoms, e.g., tin, can be approximately 0.05 atomic % to approximately 1.5 atomic %. For example, the amount of the first impurity atoms, e.g., tin, can be approximately 0.1 atomic % to approximately 1 atomic %. For example, the amount of the first impurity atoms, e.g., tin, can be approximately 0.5 atomic % to approximately 1 atomic %. Or, for example, the amount of the first impurity atoms, e.g., tin, can be approximately 0.01 atomic % to approximately 0.5 atomic %. For example, the amount of the first impurity atoms, e.g., tin, can be approximately 0.1 atomic % to approximately 0.5 atomic %. Additionally, or alternatively, the amount of second impurity atoms, e.g., germanium, can be approximately 0.001 atomic % to approximately 2 atomic %. For example, the amount of the second impurity atoms, e.g., germanium, can be approximately 0.01 atomic % to approximately 2 atomic %. For example, the amount of second impurity atoms, e.g., germanium, can be approximately 0.05 atomic % to approximately 1.5 atomic %. For example, the amount of second impurity atoms, e.g., germanium, can be approximately 0.1 atomic % to approximately 1 atomic %. For example, the amount of second impurity atoms, e.g., germanium, can be approximately 0.5 atomic % to approximately 1 atomic %. Or, for example, the amount of second impurity atoms, e.g., germanium, can be approximately 0.01 atomic % to approximately 0.5 atomic %. For example, the amount of second impurity atoms, e.g., germanium, can be approximately 0.1 atomic % to approximately 0.5 atomic %. Any suitable combination of amounts of the first and second impurities, e.g., tin and germanium, can be used. In one specific example, the amount of the second impurity atoms, e.g., germanium, is approximately 0.001 atomic % to approximately 2 atomic %, and the amount of the first impurity atoms, e.g., tin, is approximately 0.001 atomic % to approximately 2 atomic %. Additionally, note that the presence of one or more other isoelectronic impurities or N or P type dopants can affect the saturation limit of a given isoelectronic impurity in the silicon. In such embodiments, the saturation limit of that impurity in the silicon is intended to include any such effects of other isoelectronic impurities or N or P type dopants.

It should be appreciated that any suitable isoelectronic impurity, or any suitable number and type of isoelectronic impurities, can be included within silicon so as to provide a silicon-based thermoelectric material having suitable thermoelectric properties. Exemplary isoelectronic impurities include C, Ge, Sn, and Pb. The amount of each such isoelectronic impurity can be, for example, 0.001 atomic % to approximately 2 atomic %. For example, the amount of each impurity independently can be approximately 0.01 atomic % to approximately 2 atomic %. For example, the amount of each impurity independently can be approximately 0.05 atomic % to approximately 1.5 atomic %. For example, the amount of each impurity independently can be approximately 0.1 atomic % to approximately 1 atomic %. For example, the amount of each impurity independently can be approximately 0.5 atomic % to approximately 1 atomic %. Or, for example, the amount of each impurity independently can be approximately 0.01 atomic % to approximately 0.5 atomic %. For example, the amount of each impurity independently can be approximately 0.1 atomic % to approximately 0.5 atomic %. The solubility of each such impurity can be affected by the presence of other impurities or dopants in the silicon.

In one illustrative embodiment, the thermoelectric material includes Si and Sn. In another illustrative embodiment, the thermoelectric material includes Si, Sn, and Ge. In another illustrative embodiment, the thermoelectric material includes Si, Sn, and Pb. In another illustrative embodiment, the thermoelectric material includes Si, Sn, and C. In another illustrative embodiment, the thermoelectric material includes Si, Sn, Ge, and Pb. In another illustrative embodiment, the thermoelectric material includes Si, Sn, Ge, and C. In another illustrative embodiment, the thermoelectric material includes Si, Sn, Ge, C, and Pb. In another illustrative embodiment, the thermoelectric material includes Si and Ge. In another illustrative embodiment, the thermoelectric material includes Si, Ge, and C. In another illustrative embodiment, the thermoelectric material includes Si, Ge, and Pb. In another illustrative embodiment, the thermoelectric material includes Si, Ge, C, and Pb. In another illustrative embodiment, the thermoelectric material includes Si and C. In another illustrative embodiment, the thermoelectric material includes Si, C, and Pb. In another illustrative embodiment, the thermoelectric material includes Si and Pb.

Additionally, it should be appreciated that the present silicon-based thermoelectric materials can be provided in the form of a bulk material, or alternatively can be provided in the form of a nanostructure such as a nanocrystal, nanowire, or nanoribbon. For example, nanocrystals can have diameters that range from 1 to 250 nm, e.g., from 1 to 100 nm. Nanowires can have aspect ratios of length to diameter greater than ten-to-one. For example, nanowires have been shown to have lower thermal conductivity and therefore higher thermoelectric figure-of-merit ZT than bulk single crystals or polycrystals of the same material. In another example, the nanowires have diameters that range from 1 to 250 nm. In yet another example, the nanowires have roughened or porous features that range in size from 1 to 100 nm. Nanoribbons can include thin films that resemble ribbons. For example, the ribbons can be less than ten microns wide and less than ten microns long, tens to hundreds of nanometers thick, and optionally can include holes within the ribbons. Such holes can have diameters that range from 1 nm to 100 nm. Such nanostructures can affect phonon thermal transport by reducing thermal conductivity while not affecting electrical properties greatly, thereby improving the thermoelectric figure-of-merit ZT. Without wishing to be bound by any theory, it is believed that including the present silicon-based thermoelectric materials within a nanostructure such as a nanocrystal, nanowire, or nanoribbon can provide further enhancements to the thermoelectric properties of the material as compared to use of the material in bulk form. Methods of forming nanocrystals, nanowires, and nanoribbons are well known in the art. Other exemplary forms of silicon in which the present isoelectronic impurities can be disposed include inverse opal, low dimension silicon material (thin film, nanostructured silicon powder, mesoporous particles, and the like), raw silicon material, wafer, and sintered structures in at least partially bulk form. For further details on various exemplary forms of silicon that can be used in the present thermoelectric materials, see the following references, the entire contents of each of which are incorporated by reference herein: Hochbaum et al., “Enhanced thermoelectric performance of rough silicon nanowires,” Nature 451: 06381, pages 163-168 (2008); PCT Patent Publication No. WO2009/026466 to Yang et al.; U.S. Patent Publication No. 2014/0116491 to Reifenberg et al.; U.S. Patent Publication No. 2011/0114146 to Scullin; U.S. Patent Publication No. 2012/0152295 to Matus et al.; U.S. Patent Publication No. 2012/0247527 to Scullin et al.; U.S. Patent Publication No. 2012/0295074 to Yi et al.; U.S. Patent Publication No. 2012/0319082 to Yi et al.; U.S. Patent Publication No. 2013/0175654 to Muckenhirn et al.; U.S. Patent Publication No. 2013/0187130 to Matus et al.; and U.S. Patent Publication No. 2014/0024163 to Aguirre et al.

As discussed above and as further emphasized here, FIGS. 1B and 1C are merely examples, which should not unduly limit the claims. One of ordinary skill in the art would recognize many variations, alternatives, and modifications. For example, the present thermoelectric materials can include any suitable form of silicon including any suitable isoelectronic impurity or combination of isoelectronic impurities. For example, the silicon can have any suitable degree of crystallinity, e.g., can be amorphous, can be polycrystalline, can be nanocrystalline, or can be single crystal, or any other suitable amount of long-range order (or lack thereof).

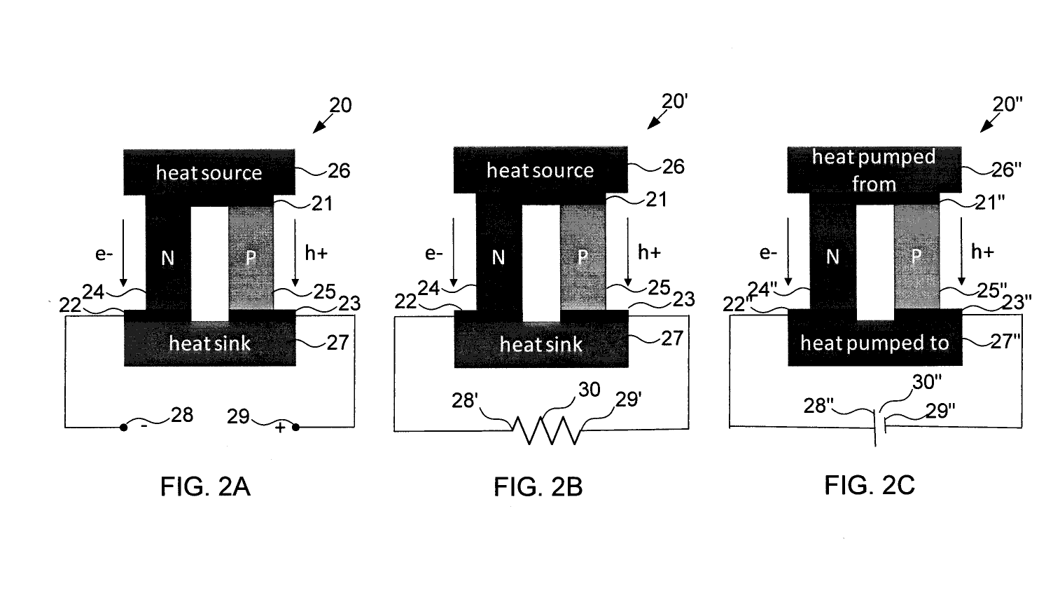

The materials provided herein, e.g., such as described above with reference to FIGS. 1B and 1C, can be included within a thermoelectric device so as to provide a device having improved thermoelectric properties. For example, FIG. 2A is a simplified diagram illustrating an exemplary thermoelectric device including a silicon-based material including silicon and one or more isoelectronic impurities, according to certain embodiments of the present invention. Thermoelectric device 20 includes first electrode 21, second electrode 22, third electrode 23, first silicon-based thermoelectric material 24, and second silicon-based thermoelectric material 25. In the illustrated embodiment, materials 24 and 25 are both silicon-based thermoelectric materials respectively including one or more isoelectronic impurities. However, it should be understood that in other embodiments, only one of materials 24 and 25 is a silicon-based thermoelectric material including one or more isoelectronic impurities, and the other of materials 24 and 25 can be any other suitable thermoelectric material known in the art or yet to be developed. Exemplary thermoelectric materials suitable for use as one of materials 24 and 25 include, but are not limited to, lead telluride (PbTe), bismuth telluride (BiTe), scutterudite, clathrates, silicides, and tellurium-silver-germanium-antimony (TeAgGeSb, or “TAGS”).

First silicon-based thermoelectric material 24 can be disposed between first electrode 21 and second electrode 22. First silicon-based thermoelectric material 24 can include silicon and atoms of a first isoelectronic impurity disposed within the silicon in an amount sufficient to scatter thermal phonons propagating through the silicon and below a respective saturation limit of the first isoelectronic impurity in the silicon, e.g., such as described above with reference to FIG. 1B. For example, first silicon-based thermoelectric material 24 can include silicon and tin atoms disposed within the silicon in an amount sufficient to scatter thermal phonons propagating through the silicon and below a saturation limit of tin in the silicon. Each of the atoms of the first isoelectronic impurity independently can substitute for a silicon atom in the silicon or can be disposed within an interstice of the silicon. For example, in one illustrative embodiment in which the first impurity is tin, each of the tin atoms can independently substitute for a silicon atom or can be disposed within an interstice of the silicon. The silicon and the atoms of the first impurity, e.g., tin, can define a single phase of the first thermoelectric material 24. In one illustrative embodiment, the amount of the first isoelectronic impurity, e.g., tin, is approximately 0.001 atomic % to approximately 2 atomic %. In another illustrative embodiment, the amount of the first isoelectronic impurity, e.g., tin, is approximately 0.01 atomic % to approximately 2 atomic %.

Optionally, first silicon-based thermoelectric material 24 also can include atoms of a second isoelectronic impurity disposed within the silicon in an amount sufficient to scatter thermal phonons propagating through the silicon and below a respective saturation limit of the second isoelectronic impurity in the silicon, e.g., such as described above with reference to FIG. 1C. For example, first silicon-based thermoelectric material 24 further can include germanium atoms disposed within the silicon in an amount sufficient to scatter thermal phonons propagating through the silicon and below a saturation limit of germanium in the silicon. Each of the atoms of the first and second isoelectronic impurities independently can substitute for a silicon atom or can be disposed within an interstice of the silicon. For example, in one illustrative embodiment in which the first impurity is tin and the second impurity is germanium, each of the tin atoms and the germanium atoms can independently substitute for a silicon atom or can be disposed within an interstice of the silicon. The silicon and the atoms of the first and second impurities, e.g., tin and germanium, can define a single phase of the first thermoelectric material 24. In one illustrative embodiment, the amount of the first isoelectronic impurity, e.g., tin, is approximately 0.001 atomic % to approximately 2 atomic %, and the amount of the second isoelectronic impurity, e.g., germanium, is approximately 0.001 atomic % to approximately 2 atomic %. In another illustrative embodiment, the amount of the first isoelectronic impurity, e.g., tin, is approximately 0.01 atomic % to approximately 2 atomic %, and the amount of the second isoelectronic impurity, e.g., germanium, is approximately 0.01 atomic % to approximately 2 atomic %. It should be appreciated that first silicon-based thermoelectric material 24 suitably can include any suitable number and type of different isoelectronic impurities, in any suitable respective amounts, and that the silicon can have any suitable degree of crystallinity, e.g., can be amorphous, can be polycrystalline, can be nanocrystalline, or can be single crystal, or any other suitable amount of long-range order (or lack thereof).

As an alternative to the second isoelectronic impurity, or in addition to the second isoelectronic impurity, first silicon-based thermoelectric material 24 also can include an N or P type dopant disposed within the silicon. For example, in the embodiment illustrated in FIG. 2A, first silicon-based thermoelectric material 24 includes an N type dopant. First silicon-based thermoelectric material 24 can consist essentially of the silicon, the atoms of the one or more isoelectronic impurities disposed therein, and an N or P type dopant. In one illustrative embodiment, first silicon-based thermoelectric material 24 can consist essentially of the silicon, tin atoms, germanium atoms, and the N type dopant.

Second silicon-based thermoelectric material 25 can be disposed between first electrode 21 and third electrode 23. Second silicon-based thermoelectric material 25 can include silicon and atoms of a third isoelectronic impurity disposed within the silicon in an amount sufficient to scatter thermal phonons propagating through the silicon and below a respective saturation limit of the third isoelectronic impurity in the silicon, e.g., such as described above with reference to FIG. 1B. Optionally, but not necessarily, the third isoelectronic impurity is of the same type or amount, or both, of the first isoelectronic impurity. For example, second silicon-based thermoelectric material 25 can include silicon and tin atoms disposed within the silicon in an amount sufficient to scatter thermal phonons propagating through the silicon and below a saturation limit of tin in the silicon. Each of the atoms of the third isoelectronic impurity independently can substitute for a silicon atom or can be disposed within an interstice of the silicon. For example, in one illustrative embodiment in which the first impurity is tin, each of the tin atoms can independently substitute for a silicon atom in the silicon or can be disposed within an interstice of the silicon. The silicon and the atoms of the third impurity, e.g., tin, can define a single phase of the second thermoelectric material 25. In one illustrative embodiment, the amount of the third isoelectronic impurity, e.g., tin, is approximately 0.001 atomic % to approximately 2 atomic %. In another illustrative embodiment, the amount of the third isoelectronic impurity, e.g., tin, is approximately 0.01 atomic % to approximately 2 atomic %.

Optionally, second silicon-based thermoelectric material 25 also can include atoms of a fourth isoelectronic impurity disposed within the silicon in an amount sufficient to scatter thermal phonons propagating through the silicon and below a respective saturation limit of the fourth isoelectronic impurity in the silicon, e.g., such as described above with reference to FIG. 1C. The fourth isoelectronic impurity optionally, but not necessarily, can be of the same type or amount, or both, as the second isoelectronic impurity (if present). For example, second silicon-based thermoelectric material 25 further can include germanium atoms disposed within the silicon in an amount sufficient to scatter thermal phonons propagating through the silicon and below a saturation limit of germanium in the silicon. Each of the atoms of the third and fourth isoelectronic impurities independently can substitute for a silicon atom or can be disposed within an interstice of the silicon. For example, in one illustrative embodiment in which the third impurity is tin and the fourth impurity is germanium, each of the tin atoms and the germanium atoms can independently substitute for a silicon atom or can be disposed within an interstice of the silicon. The silicon and the atoms of the third and fourth impurities, e.g., tin and germanium, can define a single phase of the thermoelectric material 25. In one illustrative embodiment, the amount of the third isoelectronic impurity, e.g., tin, is approximately 0.001 atomic % to approximately 2 atomic %, and the amount of the fourth isoelectronic impurity, e.g., germanium, is approximately 0.001 atomic % to approximately 2 atomic %. In another illustrative embodiment, the amount of the third isoelectronic impurity, e.g., tin, is approximately 0.01 atomic % to approximately 2 atomic %, and the amount of the fourth isoelectronic impurity, e.g., germanium, is approximately 0.01 atomic % to approximately 2 atomic %. It should be appreciated that second silicon-based thermoelectric material 25 suitably can include any additional number and type of isoelectronic impurities, in any suitable respective amounts, and that the silicon can have any suitable degree of crystallinity, e.g., can be amorphous, can be polycrystalline, can be nanocrystalline, or can be single crystal, or any other suitable amount of long-range order (or lack thereof).

As an alternative to the fourth isoelectronic impurity, or in addition to the fourth isoelectronic impurity, second silicon-based thermoelectric material 25 also can include an N or P type dopant disposed within the silicon. For example, in the embodiment illustrated in FIG. 2A, second silicon-based thermoelectric material 25 includes a P type dopant. Second silicon-based thermoelectric material 25 can consist essentially of the silicon, the atoms of the one or more isoelectronic impurities disposed therein, and an N or P type dopant. In one illustrative embodiment, second silicon-based thermoelectric material 25 can consist essentially of the silicon, tin atoms, germanium atoms, and the P type dopant. It should be appreciated that in some embodiments, first silicon-based thermoelectric material 24 and second silicon-based thermoelectric material 25 can include substantially the same isoelectronic impurities as one another, in substantially the same amounts as one another, and can include different dopants than one another. In one nonlimiting example, first silicon-based thermoelectric material 24 and second silicon-based thermoelectric material 25 both include tin and germanium in the same amounts as one another, e.g., respectively between approximately 0.001 atomic % to approximately 2 atomic % for each of tin and germanium, while material 24 includes an N type dopant and material 25 includes a P type dopant. In another nonlimiting example, first silicon-based thermoelectric material 24 and second silicon-based thermoelectric material 25 both include tin and germanium in the same amounts as one another, e.g., respectively between approximately 0.01 atomic % to approximately 2 atomic % for each of tin and germanium, while material 24 includes an N type dopant and material 25 includes a P type dopant. In other embodiments, first silicon-based thermoelectric material 24 and second silicon-based thermoelectric material 25 can include different isoelectronic impurities than one another in any respectively suitable amount, or the same isoelectronic impurities as one another but in different amounts than one another, or can include the same dopants as one another. Other combinations of impurities and dopants readily can be envisioned. Additionally, the silicon can be similar in materials 24 and 25 or can be different between materials 24 and 25.

One or both of first and second silicon-based materials 24, 25 can be in the form of a bulk material, or alternatively can be provided in the form of a nanostructure such as a nanocrystal, nanowire, or nanoribbon. Use of nanocrystals, nanowires, and nanoribbons in thermoelectric devices is known. Other exemplary forms of silicon in which the present isoelectronic impurities can be disposed include low dimension silicon material (thin film, nanostructured silicon powder, mesoporous particles, and the like), raw silicon material, wafer, and sintered structures in at least partially bulk form. In one nonlimiting, illustrative embodiment, materials 24 or 25, or both, can be based on sintered silicon nanowires prepared in a manner analogous to that described in US Patent Publication No. 2014/0116491 to Reifenberg et al.

Thermoelectric device 20 can be configured to generate an electric current flowing between first electrode 21 and second electrode 24 through first thermoelectric material 24 based on the first and second electrodes being at different temperatures than one another. For example, first electrode 21 can be in thermal and electrical contact with first silicon-based thermoelectric material 24, with second silicon-based thermoelectric material 25, and with a first body, e.g., heat source 26. Second electrode 22 can be in thermal and electrical contact with first silicon-based thermoelectric material 24, and with a second body, e.g., heat sink 27. Third electrode 23 can be in thermal and electrical contact with second silicon-based thermoelectric material 25 and with the second body, e.g., heat sink 27. Accordingly, first and second silicon-based thermoelectric materials 24, 25 can be configured electrically in series with one another, and thermally in parallel with one another between the first body, e.g., heat source 26, and the second body, e.g., heat sink 27. Note that heat source 26 and heat sink 27 can be, but need not necessarily be, considered to be part of thermoelectric device 20.

In the exemplary embodiment illustrated in FIG. 2A, first silicon-based thermoelectric material 24 includes silicon having disposed therein one or more isoelectronic impurities and an N type dopant, and second silicon-based thermoelectric material 25 includes silicon having disposed therein one or more isoelectronic impurities and a P type dopant. First silicon-based thermoelectric material 24 can be considered to define an N type thermoelectric leg of device 20, and second silicon-based thermoelectric material 25 can be considered to define a P type thermoelectric leg of device 20. Responsive to a temperature differential or gradient between the first body, e.g., heat source 26, and the second body, e.g., heat sink 27, electrons (e−) flow from first electrode 21 to second electrode 22 through first silicon-based thermoelectric material 24, and holes (h+) flow from first electrode 21 to third electrode 23 through second silicon-based thermoelectric material 25, thus generating a current. In one illustrative example, first silicon-based thermoelectric material 24 and second silicon-based thermoelectric material 25 are connected electrically to each other and thermally to first body 26, e.g., heat source, via first electrode 21. As heat flows from first body 26 to second body 27, e.g., heat sink, through the first and second thermoelectric materials 24, 25 in parallel, negative electrons travel from the hot to cold end of the first thermoelectric material 24 and positive holes travel from the hot to cold end of the second thermoelectric material 25. An electrical potential or voltage between electrodes 28 and 29 is created by having each material leg in a temperature gradient with electric current flow created as the first and second thermoelectric materials 24, 25 are connected together electrically in series and thermally in parallel. Isoelectronic impurities included in materials 24 or 25, or both, can improve the figure of merit ZT of the respective material, resulting in a higher energy conversion efficiency for a given temperature difference between first body 26 and second body 27. For a given heat flow, this improved efficiency can result in a higher power output of device 20.

The current generated by device 20 can be utilized in any suitable manner. For example, second electrode 22 can be coupled to anode 28 via a suitable connection, e.g., an electrical conductor, and third electrode 23 can be coupled to cathode 29 via a suitable connection, e.g., an electrical conductor. Anode 28 and cathode 29 can be connected to any suitable electrical device so as to provide a voltage potential or current to such device. Exemplary electrical devices include batteries, capacitors, motors, and the like. For example, FIG. 2B is a simplified diagram illustrating an alternative thermoelectric device including a silicon-based thermoelectric material including one or more isoelectronic impurities, according to certain embodiments of the present invention. Device 20′ illustrated in FIG. 2B is configured analogously to device 20 illustrated in FIG. 2A, but including alternative anode 28′ and alternative cathode 29′ that are respectively coupled to first and second terminals of resistor 30. Resistor 30 can be a stand-alone device or can be a portion of another electrical device to which anode 28′ and cathode 29′ can be coupled. Exemplary electrical devices include batteries, capacitors, motors, and the like.

Other types of thermoelectric devices suitably can include the present silicon-based thermoelectric materials. For example, FIG. 2C is a simplified diagram illustrating another exemplary alternative thermoelectric device including a silicon-based material including silicon and one or more isoelectronic impurities, according to certain embodiments of the present invention. Thermoelectric device 20″ includes first electrode 21″, second electrode 22″, third electrode 23″, first silicon-based thermoelectric material 24″, and second silicon-based thermoelectric material 25″.

First silicon-based thermoelectric material 24″ can be disposed between first electrode 21″ and second electrode 22″. First silicon-based thermoelectric material 24″ can include silicon and atoms of a first isoelectronic impurity disposed within the silicon in an amount sufficient to scatter thermal phonons propagating through the silicon and below a respective saturation limit of the first isoelectronic impurity in the silicon, e.g., such as described above with reference to FIG. 1B. For example, first silicon-based thermoelectric material 24″ can include silicon and tin atoms disposed within the silicon in an amount sufficient to scatter thermal phonons propagating through the silicon and below a saturation limit of tin in the silicon. Each of the atoms of the first isoelectronic impurity independently can substitute for a silicon atom or can be disposed within an interstice of the silicon. For example, in one illustrative embodiment in which the first impurity is tin, each of the tin atoms can independently substitute for a silicon atom or can be disposed within an interstice of the silicon. The silicon and the atoms of the first impurity, e.g., tin, can define a single phase of the first thermoelectric material 24″. In one illustrative embodiment, the amount of the first isoelectronic impurity, e.g., tin, is approximately 0.001 atomic % to approximately 2 atomic %. In another illustrative embodiment, the amount of the first isoelectronic impurity, e.g., tin, is approximately 0.01 atomic % to approximately 2 atomic %.

Optionally, first silicon-based thermoelectric material 24″ also can include atoms of a second isoelectronic impurity disposed within the silicon in an amount sufficient to scatter thermal phonons propagating through the silicon and below a respective saturation limit of the second isoelectronic impurity in the silicon, e.g., such as described above with reference to FIG. 1C. For example, first silicon-based thermoelectric material 24″ further can include germanium atoms disposed within the silicon in an amount sufficient to scatter thermal phonons propagating through the silicon and below a saturation limit of germanium in the silicon. Each of the atoms of the first and second isoelectronic impurities independently can substitute for a silicon atom or can be disposed within an interstice of the silicon. For example, in one illustrative embodiment in which the first impurity is tin and the second impurity is germanium, each of the tin atoms and the germanium atoms can independently substitute for a silicon atom or can be disposed within an interstice of the silicon. The silicon and the atoms of the first and second impurities, e.g., tin and germanium, can define a single phase of the thermoelectric material 24″. In one illustrative embodiment, the amount of the first isoelectronic impurity, e.g., tin, is approximately 0.001 atomic % to approximately 2 atomic %, and the amount of the second isoelectronic impurity, e.g., germanium, is approximately 0.001 atomic % to approximately 2 atomic %. In another illustrative embodiment, the amount of the first isoelectronic impurity, e.g., tin, is approximately 0.01 atomic % to approximately 2 atomic %, and the amount of the second isoelectronic impurity, e.g., germanium, is approximately 0.01 atomic % to approximately 2 atomic %. It should be appreciated that first silicon-based thermoelectric material 24″ suitably can include any suitable number and type of different isoelectronic impurities, in any suitable respective amounts, and that the silicon can have any suitable degree of crystallinity, e.g., can be amorphous, can be polycrystalline, can be nanocrystalline, or can be single crystal, or any other suitable amount of long-range order (or lack thereof).

As an alternative to the second isoelectronic impurity, or in addition to the second isoelectronic impurity, first silicon-based thermoelectric material 24″ also can include an N or P type dopant disposed within the silicon. For example, in the embodiment illustrated in FIG. 2C, first silicon-based thermoelectric material 24″ includes an N type dopant. First silicon-based thermoelectric material 24″ can consist essentially of the silicon, the atoms of the one or more isoelectronic impurities disposed therein, and an N or P type dopant. In one illustrative embodiment, first silicon-based thermoelectric material 24″ can consist essentially of the silicon, tin atoms, germanium atoms, and the N type dopant.

Second silicon-based thermoelectric material 25″ can be disposed between first electrode 21″ and third electrode 23″. Second silicon-based thermoelectric material 25″ can include silicon and atoms of a third isoelectronic impurity disposed within the silicon in an amount sufficient to scatter thermal phonons propagating through the silicon and below a respective saturation limit of the third isoelectronic impurity in the silicon, e.g., such as described above with reference to FIG. 1B. Optionally, but not necessarily, the third isoelectronic impurity can be the same as the first isoelectronic impurity. For example, second silicon-based thermoelectric material 25″ can include silicon and tin atoms disposed within the silicon in an amount sufficient to scatter thermal phonons propagating through the silicon and below a saturation limit of tin in the silicon. Each of the atoms of the third isoelectronic impurity independently can substitute for a silicon atom or can be disposed within an interstice of the silicon. For example, in one illustrative embodiment in which the third impurity is tin, each of the tin atoms can independently substitute for a silicon atom or can be disposed within an interstice of the silicon. The silicon and the atoms of the third impurity, e.g., tin, can define a single phase of the second thermoelectric material 25″. In one illustrative embodiment, the amount of the third isoelectronic impurity, e.g., tin, is approximately 0.001 atomic % to approximately 2 atomic %. In another illustrative embodiment, the amount of the third isoelectronic impurity, e.g., tin, is approximately 0.01 atomic % to approximately 2 atomic %.

Optionally, second silicon-based thermoelectric material 25″ also can include atoms of a fourth isoelectronic impurity disposed within the silicon in an amount sufficient to scatter thermal phonons propagating through the silicon and below a respective saturation limit of the fourth isoelectronic impurity in the silicon, e.g., such as described above with reference to FIG. 1C. Optionally, but not necessarily, the fourth isoelectronic impurity can be the same as the second isoelectronic impurity (if present). For example, second silicon-based thermoelectric material 25″ further can include germanium atoms disposed within the silicon in an amount sufficient to scatter thermal phonons propagating through the silicon and below a saturation limit of germanium in the silicon. Each of the atoms of the third and fourth isoelectronic impurities independently can substitute for a silicon atom or can be disposed within an interstice of the silicon. For example, in one illustrative embodiment in which the third impurity is tin and the fourth impurity is germanium, each of the tin atoms and the germanium atoms can independently substitute for a silicon atom or can be disposed within an interstice of the silicon. The silicon and the atoms of the third and fourth impurities, e.g., tin and germanium, can define a single phase of the thermoelectric material 25″. In one illustrative embodiment, the amount of the third isoelectronic impurity, e.g., tin, is approximately 0.001 atomic % to approximately 2 atomic %, and the amount of the fourth isoelectronic impurity, e.g., germanium, is approximately 0.001 atomic % to approximately 2 atomic %. In another illustrative embodiment, the amount of the third isoelectronic impurity, e.g., tin, is approximately 0.01 atomic % to approximately 2 atomic %, and the amount of the fourth isoelectronic impurity, e.g., germanium, is approximately 0.01 atomic % to approximately 2 atomic %. It should be appreciated that second silicon-based thermoelectric material 25″ suitably can include any suitable number and type of different isoelectronic impurities, in any suitable respective amounts, and that the silicon can have any suitable degree of crystallinity, e.g., can be amorphous, can be polycrystalline, can be nanocrystalline, or can be single crystal, or any other suitable amount of long-range order (or lack thereof).

As an alternative to the fourth isoelectronic impurity, or in addition to the fourth isoelectronic impurity, second silicon-based thermoelectric material 25″ also can include an N or P type dopant disposed within the silicon. For example, in the embodiment illustrated in FIG. 2C, second silicon-based thermoelectric material 25″ includes a P type dopant. Second silicon-based thermoelectric material 25″ can consist essentially of the silicon, the atoms of the one or more isoelectronic impurities disposed therein, and an N or P type dopant. In one illustrative embodiment, second silicon-based thermoelectric material 25″ can consist essentially of the silicon, tin atoms, germanium atoms, and the P type dopant. It should be appreciated that in some embodiments, first silicon-based thermoelectric material 24″ and second silicon-based thermoelectric material 25″ can include substantially the same isoelectronic impurities as one another, in substantially the same amounts as one another, and can include different dopants than one another. In one nonlimiting example, first silicon-based thermoelectric material 24″ and second silicon-based thermoelectric material 25″ both include tin and germanium in the same amounts as one another, e.g., respectively between approximately 0.001 atomic % to approximately 2 atomic %, while material 24″ includes an N type dopant and material 25″ includes a P type dopant. In another nonlimiting example, first silicon-based thermoelectric material 24″ and second silicon-based thermoelectric material 25″ both include tin and germanium in the same amounts as one another, e.g., respectively between approximately 0.01 atomic % to approximately 2 atomic %, while material 24″ includes an N type dopant and material 25″ includes a P type dopant. In other embodiments, first silicon-based thermoelectric material 24″ and second silicon-based thermoelectric material 25″ can include different isoelectronic impurities than one another in any respective amount, or the same isoelectronic impurities as one another but in different amounts than one another, or can include the same dopants as one another. Other combinations of impurities and dopants readily can be envisioned. Additionally, the silicon can be similar in materials 24″ and 25″ or can be different between materials 24″ and 25″.

One or both of first and second silicon-based materials 24″, 25″ can be in the form of a bulk material, or alternatively can be provided in the form of a nanostructure such as a nanocrystal, nanowire, or nanoribbon. Use of nanocrystals, nanowires, and nanoribbons in thermoelectric devices is known. Other exemplary forms of silicon in which the present isoelectronic impurities can be disposed include inverse opal, low dimension silicon material (thin film, nanostructured silicon powder, mesoporous particles, and the like), raw silicon material, wafer, and sintered structures in at least partially bulk form. In one nonlimiting, illustrative embodiment, materials 24 or 25, or both, can be based on sintered silicon nanowires prepared in a manner analogous to that described in US Patent Publication No. 2014/0116491 to Reifenberg et al.

Thermoelectric device 20″ can be configured to pump heat from first electrode 21″ to second electrode 24″ through first thermoelectric material 24″ based on a voltage applied between the first and second electrodes. For example, first electrode 21″ can be in thermal and electrical contact with first silicon-based thermoelectric material 24″, with second silicon-based thermoelectric material 25″, and with a first body 26″ from which heat is to be pumped. Second electrode 22″ can be in thermal and electrical contact with first silicon-based thermoelectric material 24″, and with a second body 27″ to which heat is to be pumped. Third electrode 23″ can be in thermal and electrical contact with second silicon-based thermoelectric material 25″ and with the second body 27″ to which heat is to be pumped. Accordingly, first and second silicon-based thermoelectric materials 24″, 25″ can be configured electrically in series with one another, and thermally in parallel with one another between the first body 26″ from which heat is to be pumped, and the second body 27″ to which heat is to be pumped. Note that first body 26″ and second body 27″ can be, but need not necessarily be, considered to be part of thermoelectric device 20″.

In the exemplary embodiment illustrated in FIG. 2C, first silicon-based thermoelectric material 24″ includes an N type dopant, and second silicon-based thermoelectric material 25″ includes a P type dopant. First silicon-based thermoelectric material 24″ can be considered to define an N type thermoelectric leg of device 20″, and second silicon-based thermoelectric material 25″ can be considered to define a P type thermoelectric leg of device 20″. Second electrode 22″ can be coupled to cathode 28″ of battery or other power supply 30″ via a suitable connection, e.g., an electrical conductor, and third electrode 23″ can be coupled to anode 29″ of battery or other power supply 30″ via a suitable connection, e.g., an electrical conductor. Responsive to a voltage applied by battery or other power supply 30″ between second electrode 22″ and third electrode 23″, electrons (e−) flow from first electrode 21″ to second electrode 22″ through first silicon-based thermoelectric material 24″, and holes (h+) flow from first electrode 21″ to third electrode 23″ through second silicon-based thermoelectric material 25″, thus pumping heat from first body 26″ to second body 27″. In one illustrative example, first silicon-based thermoelectric material 24″ and second silicon-based thermoelectric material 25″ are connected electrically to each other and to first body 26″ from which heat is pumped, via first electrode 21″. As electric current is injected from battery or other power supply 30″ into the couple flowing from second material 25″ to first material 24″, which are electrically in series and thermally in parallel, negative electrons of first material 24″ and positive holes of second material 25″ travel from one end of the corresponding thermoelectric material to the other. Heat is pumped in the same direction as the electron and hole movement, creating a temperature gradient. If the direction of the electrical current is reversed, so will the direction of electron and hole movement, and heat pumping. Isoelectronic impurities included in materials 24″ or 25″, or both, can improve the figure of merit ZT of the respective material, resulting in an improved coefficient of performance (COP) for a given temperature difference between first body 26″ and second body 27″. For a given electrical current, this improved COP can result in more efficient heat pumping or a lower input power applied by battery or other power supply 30″, or both. The pumping of heat from first body 26″ to second body 27″ suitably can be used to cool first body 26″. For example, first body 26″ can include a computer chip.

As discussed above and as further emphasized here, FIGS. 2A-2C are merely examples, which should not unduly limit the claims. One of ordinary skill in the art would recognize many variations, alternatives, and modifications. For example, the present thermoelectric materials can be used in any suitable thermoelectric or non-thermoelectric device. Additionally, the embodiments illustrated in FIGS. 2A-2C suitably can use materials other than those specifically illustrated in FIGS. 1B-1C.

As noted above, the present silicon-based thermoelectric materials can have enhanced thermoelectric properties, e.g., can have an increased figure of merit ZT, a decreased thermal conductivity, an increased thermal conductivity, or an increased Seebeck coefficient, or any suitable combination of such improvements. Such enhanced thermoelectric properties can provide enhancements in performance of thermoelectric devices such as exemplary devices 20, 20′, and 20″ respectively illustrated in FIGS. 2A-2C.

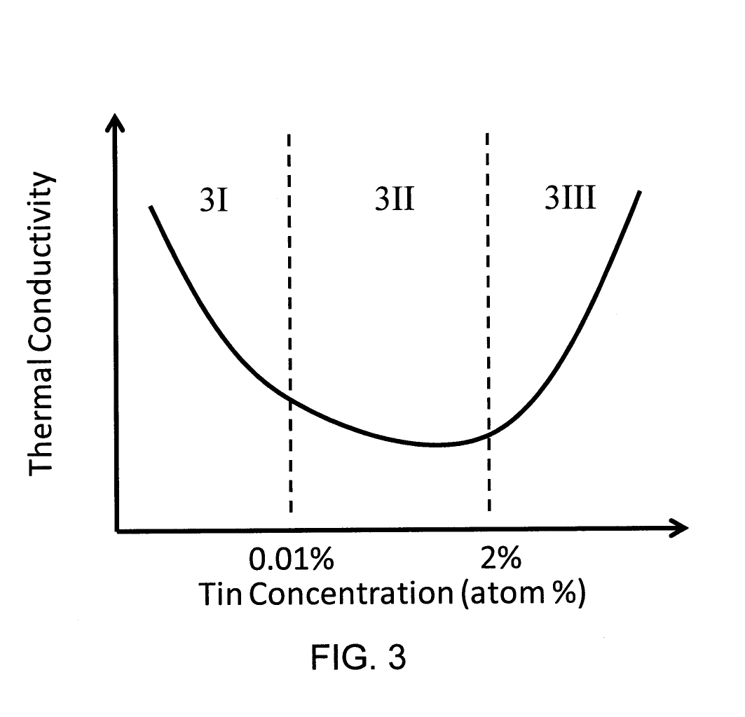

As one example, FIG. 3 is a simplified diagram illustrating an exemplary effect of concentration of an isoelectronic impurity such as tin (Sn) on thermal conductivity of a silicon-based thermoelectric material, according to certain embodiments of the present invention. As shown, it can be useful to provide the tin impurity atomic concentration in zone 3II, corresponding to a range from about 0.001 or 0.01 atomic % to about 2 atomic %, which can be anticipated to provide a relatively lower thermal conductivity. Without wishing to be bound by any theory, it is believed that within a relatively low impurity concentration zone 3I, phonon scattering is dominated by traditional scattering mechanisms (e.g., phonon-electron, phonon-phonon, or grain boundary scattering, phonon-dopant). The residue or low dose Sn impurity atoms is believed to have a relatively limited effect to lower the thermal conductivity. Without wishing to be bound by any theory, it is believed that within a relatively high doping concentration zone 3III, phase segregation of Sn and base material Si can occur and can cause an increase in thermal conductivity. Without wishing to be bound by any theory, it is believed that within middle doping concentration zone 3II, e.g., in a range from approximately 0.01 atomic % to approximately 2 atomic %, the phonon scattering rate can be substantially increased, e.g., because of scattering from relatively large tin impurities within the silicon base material, e.g., that substitute for the silicon atoms in the silicon base material. Without wishing to be bound by any theory, it is believed that such an effect can be obtained in any form of silicon, including but not limited to nanoribbons, nanocrystals, nanowires, inverse opal, low dimension silicon material (thin film, nanostructured silicon powder, mesoporous particles, and the like), raw silicon material, wafer, and sintered structures in at least partially bulk form. The silicon can have any suitable degree of crystallinity, e.g., can be amorphous, can be polycrystalline, can be nanocrystalline, or can be single crystal, or any other suitable amount of long-range order (or lack thereof).

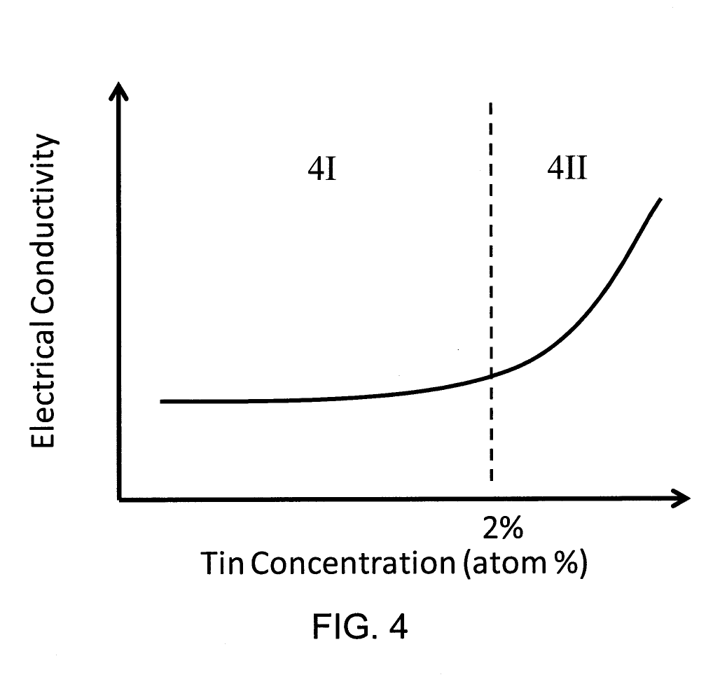

As another example, FIG. 4 is a simplified diagram illustrating an exemplary effect of concentration of an isoelectronic impurity such as tin (Sn) on electrical conductivity of a silicon-based thermoelectric material, according to certain embodiments of the present invention. As shown, it can be useful to provide the tin doping atomic concentration in zone 4I, e.g., corresponding to below about 2 atomic %, which can be expected to have a relatively low impact on electrical conductivity. Without wishing to be bound by any theory, it is believed that in the lower Sn doping concentration zone 4I, electrical conductivity is affected to a relatively low extent because of the isoelectronic nature of the impurity, e.g., substitutional impurity. More specifically, the impurity substantially does not introduce to the silicon based material any extra donors or acceptors to contribute the either hole or electron conduction in the semiconductor silicon material. But when the doping concentration of tin is increased, for example, in zone 4II, it can be expected that electrical conductivity increases rapidly as a result of shorting through tin phase segregation with silicon base material. Without wishing to be bound by any theory, it is believed that such an effect can be obtained in any form of silicon, including but not limited to nanoribbons, nanocrystals, nanowires, inverse opal, low dimension silicon material (thin film, nanostructured silicon powder, mesoporous particles, and the like), raw silicon material, wafer, and sintered structures in at least partially bulk form. For example, arsenic doping in thin films previously has been used to reduce the thermal conductivity by a factor of >2. Without wishing to be bound by any theory, it is believed that tin can be expected to have an even greater (3-10×) impact in low dimension silicon material (thin film, nanostructured silicon powder, mesoporous Si particles, and the like) at similar atomic concentrations as As because Sn has a larger mass than As. Typically silicon is doped by As to improve its electrical conductivity while maintaining a relatively high thermal conductivity desirable for many electronic applications. But in thermoelectric application, it can be useful to maintain the electrical conductivity while dramatically reducing the thermal conductivity, e.g., by introducing one or more isoelectronic impurities such as Sn, Ge, C or Pb, or a combination thereof. The silicon can have any suitable degree of crystallinity, e.g., can be amorphous, can be polycrystalline, can be nanocrystalline, or can be single crystal, or any other suitable amount of long range order (or lack thereof).

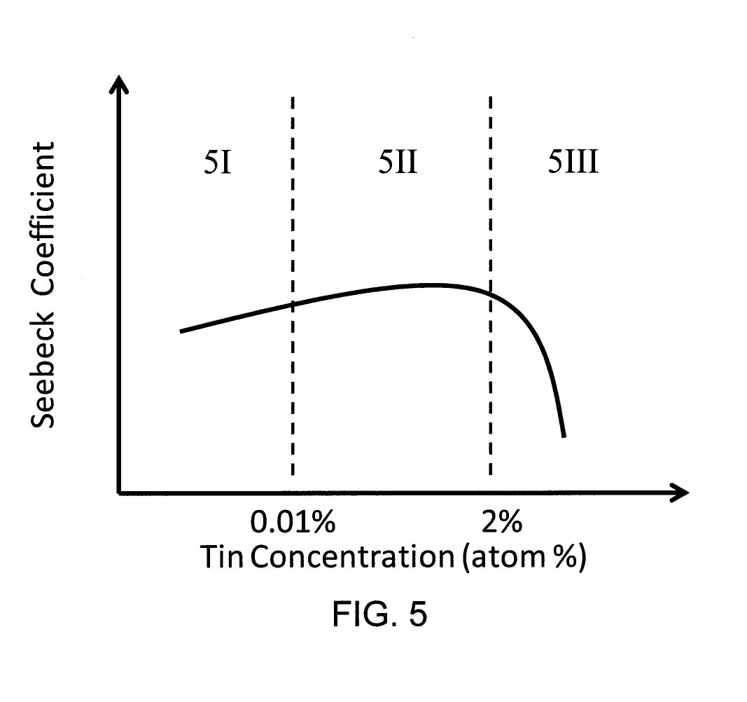

As another example, FIG. 5 is a simplified diagram illustrating an exemplary effect of concentration of an isoelectronic impurity such as tin (Sn) on the Seebeck coefficient of a silicon-based thermoelectric material, according to certain embodiments of the present invention. As shown, it can be useful to provide the tin doping atomic concentration in zone 5I, e.g., corresponding to a range from about 0.001 or 0.01 atomic % to about 2 atomic % so as to provide a higher value of Seebeck coefficient. Without wishing to be bound by any theory, it is believed that in the lower Sn concentration zone 5I, tin concentration can be too low to significantly modify band structure, leaving the Seebeck coefficient almost unchanged. Without wishing to be bound by any theory, it is believed that in the relatively high tin concentration zone 5III, phase segregation of tin from silicon can cause electrical shorting and bands overlapping. In zone 5III, the material can be expected to become substantially metal-like with its Seebeck coefficient falling quickly as the tin concentration increases although electrical conductivity also increases. Such a zone may not achieve a satisfactory or highest thermoelectric figure-of merit ZT. Without wishing to be bound by any theory, it is believed that when the tin concentration is controlled within a middle range corresponding to zone 5II, for example, between 0.001 or 0.01 atomic % and 2 atomic %, the tin substitute impurities can cause band bending and changes in band gap, leading to an increase in Seebeck coefficient.

Additionally, as noted further above, nanostructuring treatment to silicon material, and specifically the formation of rough nanostructured silicon material, is believed to reduce the thermal conductivity through disruption of the phonon dispersion relationship and increase scattering. Introducing proper concentration of isoelectronic impurities into nanostructured silicon material can further modify the phonon dispersion relationship to cause even lower thermal conductivity than that can be expected merely from simple additive effect the two above approaches. For example, tin atoms, especially those near particular local rough surfaces of silicon nanowires, can be expected to enhance the role of roughness in reducing the thermal conductivity by strengthening the scattering mechanism associated with the nanoscale roughness of the local rough surfaces of the silicon nanowires. The same is true for other nanostructures such as holey silicon, where the presence of tin atoms near the structured regions can be expected to enhance the strength of the associated phonon scattering mechanism. This phonon scattering enhancement is an addition to the direct impurity scattering mechanism that applies both in bulk and nanostructured silicon material, as would be expected from Matthiessen's rule for scattering.

Any suitable combination of Sn, Pb, Ge, C, and other isoelectronic impurities can be disposed in the silicon base material (illustratively, at least partially crystalline silicon) up to different levels limited by corresponding solid solubility. Additionally, the electrical doping properties of the silicon base material having the electronic impurities therein, e.g., Sn, Pb, C, or Ge, or any combination thereof, optionally can further be tuned by doping group III or V dopants (which also can be referred to as impurities, although they may not be isoelectronic) in a suitable amount, e.g., to about 5×10¹⁸ atoms/cm³ with either B or P to control the electrical conductivity for improving the thermoelectric power factor. Correspondingly the present materials can provide N or P type silicon base thermoelectric material (either pre-treated to include nanostructures or doped with isoelectronic impurities such as Sn, Ge, C, or Pb, or any combination thereof) that can be applied respectively for N or P legs of a thermoelectric device such as described above with reference to FIGS. 2A-2C. The doping processes for the N and P type impurities could be done in series or simultaneously with the doping of isoelectronic impurities such as Sn, Ge, C, or Pb.

As discussed above and as further emphasized here, FIGS. 3-5 are merely examples, which should not unduly limit the claims. One of ordinary skill in the art would recognize many variations, alternatives, and modifications. For example, the particular thermoelectric properties of a given material can vary depending on the form and crystallinity (or lack thereof) of the silicon and any isoelectronic impurities and N or P type dopants therein.

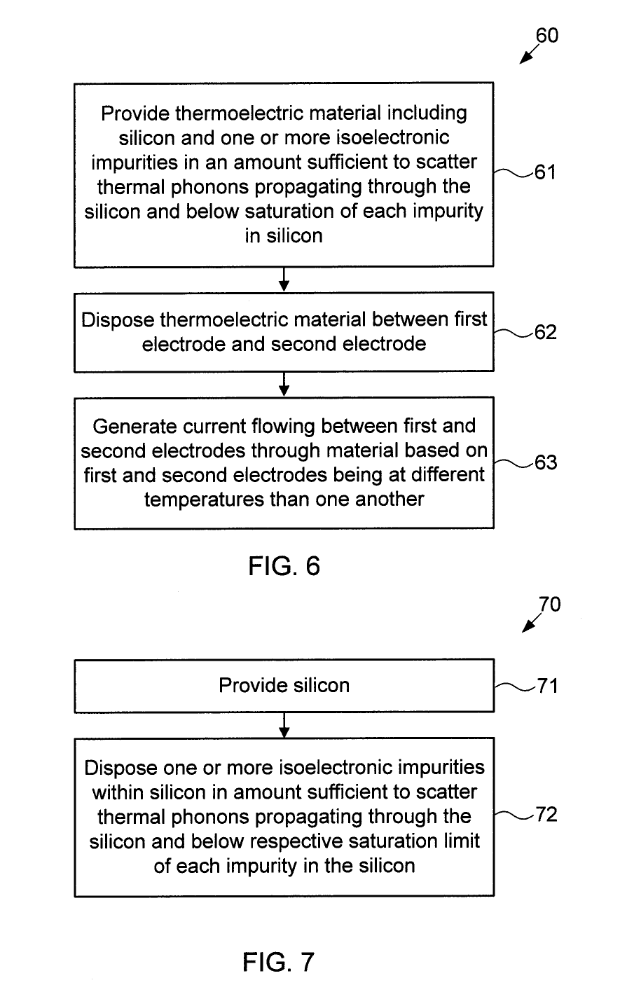

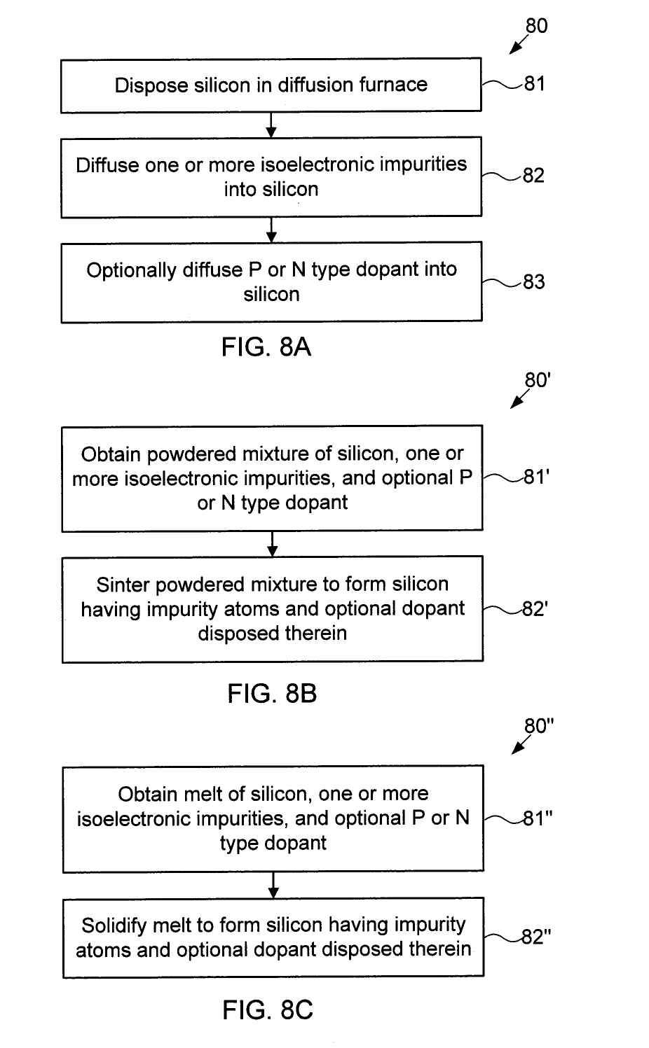

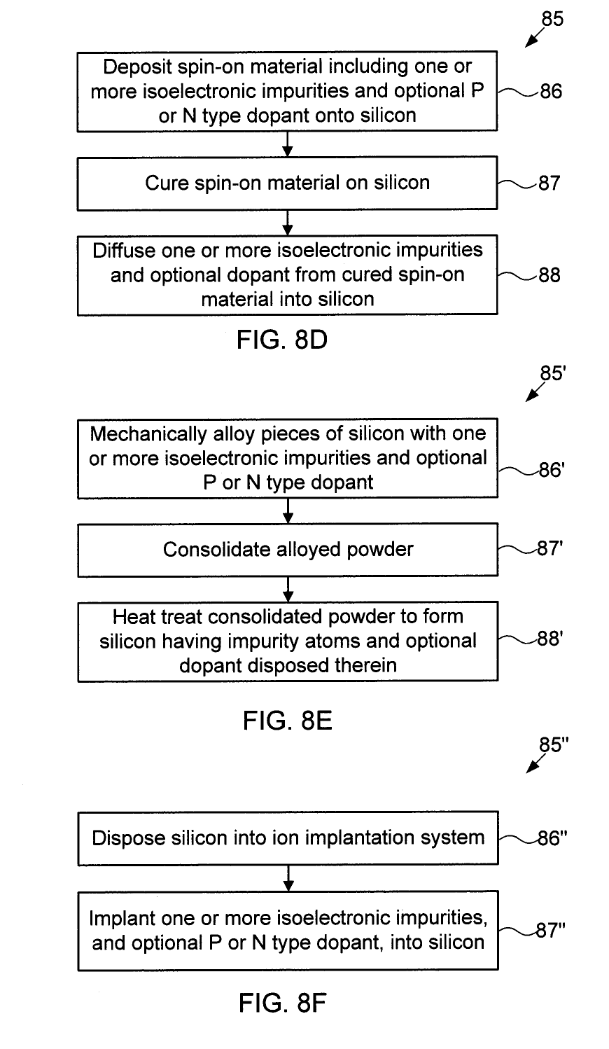

FIG. 6 is a simplified diagram illustrating an exemplary method for making and using a thermoelectric device including a silicon-based thermoelectric material including silicon and one or more isoelectronic impurities, according to certain embodiments of the present invention. Method 60 can include providing a thermoelectric material including silicon and one or more isoelectronic impurities in an amount sufficient to scatter thermal phonons propagating through the silicon and below a saturation limit of each impurity in the silicon (61). Some non-limiting examples of silicon-based thermoelectric materials are described further above with reference to FIGS. 1B and 1C. Some non-limiting examples of devices in which silicon-based thermoelectric materials can be used are described further above with reference to FIGS. 2A-2C. Some non-limiting examples of thermoelectric properties of certain exemplary thermoelectric materials are described further above with reference to FIGS. 3-5. Exemplary methods of preparing silicon-based thermoelectric materials are described further below with reference to FIGS. 7 and 8A-8F.

Referring again to FIG. 6, method 60 further can include disposing the thermoelectric material between a first electrode and a second electrode (62). For example, as described above with reference to FIG. 2A, first thermoelectric material 24 can be disposed between first electrode 21 and second electrode 22, and second thermoelectric material 25 can be disposed between first electrode 21 and third electrode 23. Methods of disposing materials between electrodes are known.

Referring again to FIG. 6, method 60 further can include generating a current flowing between the first and second electrodes through the material based on the first and second electrodes being at different temperatures than one another (63). For example, as described above with reference to FIG. 2A, first electrode 21 can be in thermal and electrical contact with first silicon-based thermoelectric material 24, with second silicon-based thermoelectric material 25, and with a first body, e.g., heat source 26. Second electrode 22 can be in thermal and electrical contact with first silicon-based thermoelectric material 24, and with a second body, e.g., heat sink 27. Third electrode 23 can be in thermal and electrical contact with second silicon-based thermoelectric material 25 and with the second body, e.g., heat sink 27. First silicon-based thermoelectric material 24 can include an N type dopant and can define an N type leg of a thermoelectric device, and second silicon-based thermoelectric material 25 can include a P type dopant and can define a P type leg of a thermoelectric device. Responsive to a temperature differential or gradient between the first body, e.g., heat source 26, and the second body, e.g., heat sink 27, electrons (e−) flow from first electrode 21 to second electrode 22 through first silicon-based thermoelectric material 24, and holes (h+) flow from first electrode 21 to third electrode 23 through second silicon-based thermoelectric material 25, thus generating a current. Isoelectronic impurities included in materials 24 or 25, or both, can improve the figure of merit ZT of the respective material, resulting in a higher energy conversion efficiency for a given temperature difference between first body 26 and second body 27. For a given heat flow, this improved efficiency can result in a higher power output of device 20.

In one illustrative embodiment, the silicon-based material provided in method 60 of FIG. 6 can include silicon, and tin atoms disposed within the silicon in an amount sufficient to scatter thermal phonons propagating through the silicon and below a saturation limit of tin in the silicon. In one illustrative embodiment, the amount of the tin atoms is approximately 0.001 atomic % to approximately 2 atomic %. In another illustrative embodiment, the amount of the tin atoms is approximately 0.01 atomic % to approximately 2 atomic %. The thermoelectric material further can include germanium atoms in an amount sufficient to scatter thermal phonons propagating through the silicon and below a saturation limit of germanium in the silicon. For example, the silicon, the tin atoms, and the germanium atoms can define a single phase of the thermoelectric material. For example, each of the tin atoms and the germanium atoms independently substitutes for a silicon atom in the silicon or is disposed within an interstice of the silicon. For example, the silicon, the tin atoms, and the germanium atoms can define a single phase of the thermoelectric material. The thermoelectric material further can include an N or P type dopant disposed within the silicon. For example, the thermoelectric material can consist essentially of the silicon, the tin atoms, the germanium atoms, and the N or P type dopant. In one illustrative embodiment, the amount of the germanium atoms is approximately 0.001 atomic % to approximately 2 atomic %, and the amount of the tin atoms is approximately 0.001 atomic % to approximately 2 atomic %. In another illustrative embodiment, the amount of the germanium atoms is approximately 0.01 atomic % to approximately 2 atomic %, and the amount of the tin atoms is approximately 0.01 atomic % to approximately 2 atomic %. However, it should be appreciated that the material can include any suitable number, type, and amounts of isoelectronic impurities disposed within the silicon, and that the silicon can have any suitable degree of crystallinity, e.g., can be amorphous, can be polycrystalline, can be nanocrystalline, or can be single crystal, or any other suitable amount of long-range order (or lack thereof).

FIG. 7 is a simplified diagram illustrating an exemplary method for preparing a silicon-based thermoelectric material including silicon and one or more isoelectronic impurities, according to certain embodiments of the present invention. Method 70 includes providing silicon (71), and disposing one or more isoelectronic impurities within the silicon in an amount sufficient to scatter thermal phonons propagating through the silicon and below the respective saturation limit of each impurity in the silicon (72). Note that steps 71 and 72 can be performed in any suitable order, and even can be performed simultaneously with one another.

In one illustrative embodiment, method 70 includes providing silicon, and disposing tin atoms within the silicon in an amount sufficient to scatter thermal phonons propagating through the silicon and below a saturation limit of tin in the silicon. In one illustrative embodiment, the amount of the tin atoms is approximately 0.001 atomic % to approximately 2 atomic %. In another illustrative embodiment, the amount of the tin atoms is approximately 0.01 atomic % to approximately 2 atomic %. Method 70 further can include disposing germanium atoms within the silicon in an amount sufficient to scatter thermal phonons propagating through the silicon and below a saturation limit of germanium in the silicon. For example, the silicon, the tin atoms, and the germanium atoms can define a single phase of the thermoelectric material. For example, method 70 can include independently substituting each of the tin atoms and the germanium atoms for a silicon atom in the silicon or disposing that tin or germanium atom within an interstice of the silicon. For example, the silicon, the tin atoms, and the germanium atoms can define a single phase of the thermoelectric material. In certain embodiments, method 70 further can include disposing an N or P type dopant within the silicon. For example, the thermoelectric material can consist essentially of the silicon, the tin atoms, the germanium atoms, and the N or P type dopant. In one illustrative embodiment, the amount of the germanium atoms can be approximately 0.001 atomic % to approximately 2 atomic %, and the amount of the tin atoms can be approximately 0.001 atomic % to approximately 2 atomic %. In another illustrative embodiment, the amount of the germanium atoms can be approximately 0.01 atomic % to approximately 2 atomic %, and the amount of the tin atoms can be approximately 0.01 atomic % to approximately 2 atomic %. However, it should be appreciated that any suitable types and amounts of one or more different isoelectronic impurities can be disposed within the silicon.

The one or more of the present isoelectronic impurities can be disposed within silicon using any suitable method or apparatus. For example, FIGS. 8A-8F are simplified diagrams respectively illustrating exemplary methods for introducing one or more isoelectronic impurities into silicon, according to certain embodiments of the present invention. It should be appreciated that FIGS. 8A-8F are not intended to be limiting, and that any other suitable method or apparatus alternatively can be used.

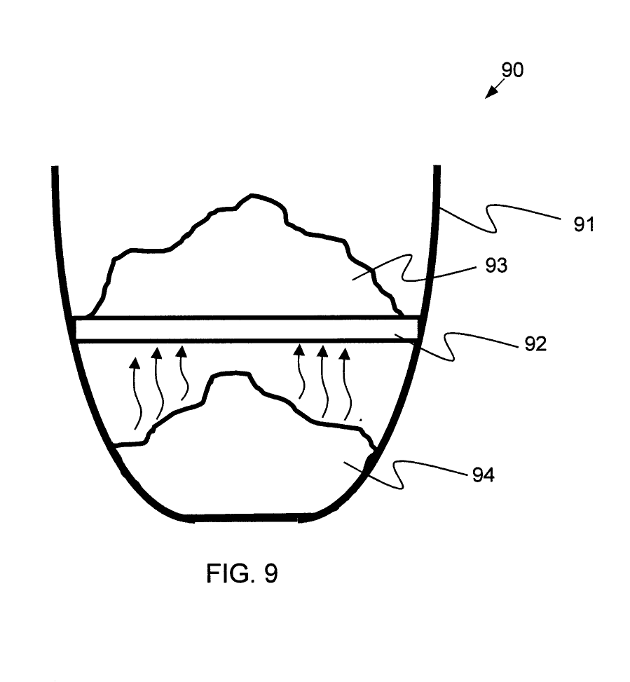

Referring to FIG. 8A, method 80 includes disposing silicon in a diffusion furnace (81). For example, FIG. 9 is a simplified diagram illustrating an exemplary apparatus that can be used to introduce one or more isoelectronic impurities into silicon, according to certain embodiments of the present invention. Apparatus 90 includes a diffusion furnace (not specifically illustrated) within which crucible 91 can be disposed. Crucible 91 includes porous disc 92 installed in the approximately middle section of crucible 91. Above the porous disc 92 a cluster of Si base material (e.g., at least partially crystalline silicon) can be disposed. The Si base material, as mentioned before, can be prepared into any suitable form, e.g., a form selected from nanoribbons, nanocrystals, nanowires, inverse opal, low dimension silicon material (thin film, nanostructured silicon powder, mesoporous particles, and the like), raw silicon material, wafer, and sintered structures in at least partially bulk form.

Referring again to FIG. 8A, method 80 further includes diffusing one or more isoelectronic impurities into the silicon (82). For example, below the porous disc 92 illustrated in FIG. 9, a powder of the one or more impurities, e.g., a plurality of isoelectronic impurity, e.g., Sn, C, Pb, or Ge, or a combination thereof, powders or small particles can be pre-disposed. The impurity can be made into powder form so that vapor phase impurity atoms can be relatively easily formed by sublimation from the solid powers of the impurity when the crucible is heated externally to about 1050° C. or higher. The impurity vapor, during the diffusion process, can be gradually incorporated into the Si base material by thermal diffusion. The whole process may last several hours to several days to ensure that the impurity is introduced in a sufficient amount, e.g., approaching the solubility of the impurity in Silicon, e.g., near 5×10¹⁹ atoms/cm³ in embodiments where the impurity is Sn. In one illustrative embodiment, Sn is diffused into the Si base material to a level of ˜5×10¹⁹ atoms/cm³ in a diffusion furnace at ˜1050° C. Optionally, Ge atoms also can be diffused into the Si base material concurrently with the Sn, or before or after the Sn is diffused into the Si base material, in an analogous manner as the Sn. Any suitable combination of one or more of C, Ge, Sn, and Pb analogously can be diffused into the Si base material.

Referring again to FIG. 8A, method 80 optionally further includes diffusing a P or N type dopant into the silicon (83). Step 83 can be performed concurrently with step 82, or alternatively can be performed before or after step 82, in an analogous manner as the impurity or using any other suitable technique known in the art. Alternatively, the P or N type dopant can be disposed within the silicon using technique other than diffusion, either before or after step 82.

FIG. 8B illustrates an alternative method 80′ for introducing one or more isoelectronic impurities into silicon. Method 80′ includes obtaining a powdered mixture of silicon, the one or more isoelectronic impurities, and optionally a P or N type dopant (81′). For example, the desired atomic % of each of the silicon, the one or more isoelectronic impurities, and the optional dopant can be obtained, e.g., from a commercial source, and can be powderized and blended together using any suitable technique. In one illustrative embodiment, pieces of silicon wafer, powders of the one or more isoelectronic impurities, e.g., tin and germanium, and optional powder of a P or N type dopant are ball milled together in an inert environment, e.g., in the presence of a nonreactive, non-oxidizing gas such as argon or nitrogen. Exemplary milling times range between about 10 minutes and four hours. Exemplary particle sizes resulting from such milling can be between about 10 nm and about 100 μm.

Method 80′ illustrated in FIG. 8B further includes sintering the powdered mixture to form silicon having the impurity atoms and the optional dopant disposed therein (82′). For example, the powdered mixture of step 81′ can be disposed within a suitable sintering furnace and sintered at a suitable temperature and pressure in an inert environment for a suitable amount of time, e.g., until the powdered mixture forms silicon having the one or more isoelectronic impurities and optional P or N type dopant disposed therein. Exemplary sintering pressures can be between about 5-100 MPa. Exemplary sintering times can be between about 0.1 to 90 minutes. Exemplary sintering temperatures can be between about 800-1300° C. In one illustrative embodiment, a powdered mixture of silicon and tin is obtained and sintered to form silicon having tin atoms suitably disposed therein. Germanium or any other isoelectronic impurity can be analogously incorporated. For example, any suitable combination of one or more of C, Ge, Sn, and Pb analogously can be incorporated into the Si base material.

FIG. 8C illustrates another alternative method 80″ for introducing one or more isoelectronic impurities into silicon. Method 80″ obtaining a melt of silicon, the one or more isoelectronic impurities, and optionally a P or N type dopant (81″). For example, the desired atomic % of each of the silicon, the one or more isoelectronic impurities, and the optional dopant can be obtained, e.g., from a commercial source, and can be melted together using any suitable technique. In one illustrative embodiment, pieces of silicon wafer, powders of the one or more isoelectronic impurities, e.g., tin and germanium, and optional powder of a P or N type dopant are melted together in an inert environment, e.g., in the presence of a nonreactive, non-oxidizing gas such as argon or nitrogen. Exemplary melt temperatures can be between about 800-1300° C., and the melt time can be sufficient to substantially form a melt of the silicon and the impurities. Longer melt times can be used to melt larger particles.

Method 80″ illustrated in FIG. 8C further includes solidifying the melt to form silicon having impurity atoms and the optional dopant disposed therein (82″). Exemplary methods of solidifying melts include quenching or the Czochralski process. For example, in one illustrative embodiment, the isoelectronic impurities can be added through molten mixing and annealing. For example, a predetermined amount of Sn, Ge, C, or Pb, or any combination thereof, which can be in solid opal or powder form can be added in a crucible to mix with silicon base material also in solid form including pure or doped silicon crystal. Then heat can be supplied to the crucible to let all solid materials completely melt. The molten material can be sufficiently mixed at one or more annealing temperatures before quenching the molten mixture back to room temperature. Other electrical impurities can be doped at the same time. Such a quenching process can result in formation of Sn (or other isoelectronic impurities) impurities within a solid silicon material, which can be at least partially crystalline, and which can further be processed to form nanostructures or other processes to enhance its thermoelectric properties. In yet another alternative embodiment, the isoelectronic impurities are incorporated using the Czochralski process to form a silicon ingot that includes such impurities. Similarly, other impurity such as B and P can also be properly added in the process so that a desired N or P-type silicon base material can be obtained, which includes a desired level of isoelectronic impurities such as tin, germanium, or lead that can be selected or optimized so as to reduce thermal conductivity or possibly increase Seebeck coefficient. Further, this silicon base material can be further processed to form nanowires or nanoholes by etching, mesoporous silicon material by growth or etching, powder material scratched from above species, or bulk-sized nanostructured silicon material by sintering the powder material, as a building material for actual N or P-type legs of thermoelectric devices. In one illustrative embodiment, a melt of silicon and tin is obtained; and the melt is solidified (e.g., at least partially crystallized) to form the silicon having the tin atoms suitably disposed therein. Germanium or any other isoelectronic impurity, or combination of isoelectronic impurities, can be analogously incorporated. For example, any suitable combination of one or more of C, Ge, Sn, and Pb analogously can be incorporated into the Si base material.

FIG. 8D illustrates an alternative method 85 for introducing one or more isoelectronic impurities into silicon. Method 85 includes depositing a spin-on material including a solvent, the one or more isoelectronic impurities, and optionally a P or N type dopant, onto silicon (86). Spin-on materials are a well-known technique for incorporating impurities into silicon. Exemplary spin speeds can be between about 1000 and 10000 revolutions per minute (RPM).

Method 85 illustrated in FIG. 8D further includes curing the spin-on material on the silicon (87). Curing can remove the solvent from the spin-on material and can bond the remaining portion of the spin-on material as a layer that is disposed on the silicon and from which the one or more impurities and optional dopant can diffuse into the silicon. In exemplary embodiments, the layer has a thickness between about 1 nm and about 1 μm. Exemplary curing temperatures can be between about 100° C. and about 1200° C. Exemplary gaseous environments in which the curing can be performed include air, vacuum, or an inert gas such as N₂ or Ar.

Method 85 illustrated in FIG. 8D further includes diffusing the one or more isoelectronic impurities and optional dopant from the cured spin-on material into the silicon (88). Diffusion is a well-known process step. Diffusion can occur in a diffusion furnace. Exemplary diffusion temperatures can be between about 900° C. and about 1300° C. The elevated temperature can cause the one or more isoelectronic impurities and optional dopant to migrate from the layer of cured spin-on material into the silicon. In one illustrative embodiment, silicon having tin atoms suitably disposed therein is obtained. Germanium or any other isoelectronic impurity can be analogously incorporated. For example, any suitable combination of one or more of C, Ge, Sn, and Pb analogously can be incorporated into the Si base material.

FIG. 8E illustrates an alternative method 85′ for introducing one or more isoelectronic impurities into silicon. Method 85′ includes mechanically alloying pieces of silicon with one or more isoelectronic impurities and an optional P or N type dopant (86′). In one example, a high energy ball mill or a planetary ball mill can be used to perform such mechanical alloying. Exemplary mechanical alloying times can be between about 10 minutes and about 12 hours in a high energy ball mill operating at greater than 1000 Hz, or between about 1 hour and about 48 hours in a planetary ball mill operating at greater than 300 RPM.

Method 85′ illustrated in FIG. 8E further includes consolidating the alloyed powder (87′). Consolidation can be performed, for example, using cold uniaxial pressing, hot uniaxial pressing, cold isostatic pressing, hot isostatic pressing, spark plasma sintering (SPS), or other devices for applying pressure or temperature, or both, to a powder, and can be under controlled atmosphere. In exemplary embodiments, the consolidation can be performed at a temperature between about 25° C. and about 1300° C. In exemplary embodiments, the consolidation can be performed at a pressure between about 5 MPa and about 2 GPa.

Method 85′ illustrated in FIG. 8E further includes heat treating the consolidated powder to form silicon having the impurity atoms and the optional dopant disposed therein (88′). Heat treatment can be performed in a furnace under an inert temperature such as nitrogen or argon. Exemplary heat treatment temperatures can be between about 1000° C. and about 1300° C. Exemplary heat treatment times can be between about 30 minutes and about 72 hours. In one illustrative embodiment, silicon having tin atoms suitably disposed therein is obtained. Germanium or any other isoelectronic impurity can be analogously incorporated. For example, any suitable combination of one or more of C, Ge, Sn, and Pb analogously can be incorporated into the Si base material.

FIG. 8F illustrates yet another alternative method 85″ for introducing one or more isoelectronic impurities into silicon. Method 85″ includes disposing silicon into an ion implantation system (86″).

Method 85″ illustrated in FIG. 8F further implanting the one or more isoelectronic impurities, and optional P or N type dopant, into the silicon (87″). For example, ions of the one or more isoelectronic impurities and optional dopant can be implanted sequentially or at the same time as one another. Exemplary implantation energies can be between about 10 keV and about 400 keV. In one illustrative embodiment, silicon having tin atoms suitably disposed therein is obtained. Germanium or any other isoelectronic impurity can be analogously incorporated. For example, any suitable combination of one or more of C, Ge, Sn, and Pb analogously can be incorporated into the Si base material.

As discussed above and as further emphasized here, FIGS. 6-8F are merely examples, which should not unduly limit the claims. One of ordinary skill in the art would recognize many variations, alternatives, and modifications. For example, the present thermoelectric materials and devices including such materials can be prepared using any suitable combination of techniques known in the art or yet to be developed. In one illustrative example, the thermoelectric material can be based on sintered silicon nanowires prepared in a manner analogous to that described in US Patent Publication No. 2014/0116491 to Reifenberg et al.

### EXAMPLES

A plurality of exemplary materials such as illustrated in FIG. 1B or 1C were prepared according to methods such as illustrated in FIGS. 7 and 8A. Certain thermoelectric properties of the materials then were measured and compared to one another. It should be appreciated that these examples are intended to be purely illustrative, and not limiting of the present invention.

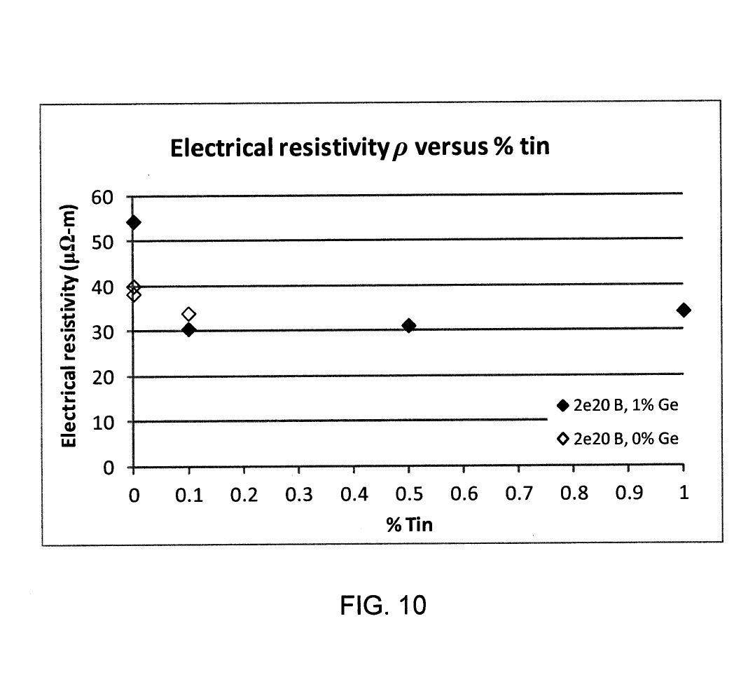

The exemplary materials were prepared by measuring out the respective desired masses of silicon wafer pieces and powders of commercially available tin, germanium, and boron (P type dopant) purchased from Sigma Aldrich (St. Louis, Mo.) and Alfa Aesar (Ward Hill, Mass.). The silicon wafer pieces had 10-30 Ohm-cm resistivity. FIGS. 10-13 indicate the amounts of the different elements in each material.

The silicon wafer pieces and powders and milling balls were inserted into a tungsten carbide jar, which was placed into a high energy mill from Spex SamplePrep (Metuchen, N.J.). The wafer pieces and powders were ball milled for approximately 120 or 240 minutes. Subsequently, the milled powder was sintered in an inert environment. More specifically, a SPS (spark plasma sintering) method was used to sinter the materials 1 gram at a time using graphite tooling. However, it should be understood that hot press or cold press methods could be used. During the sintering, the materials were subjected to a pressure of 80 MPa and heated at a rate of approximately 200° C./minute to a temperature of approximately 1200° C., and held at 1200° C. for approximately 10 minutes before cooling. The properties of the resulting bulk material were measured. Specifically, a C-THERM TCI™ thermal conductivity instrument (C-THERM Technologies Ltd., Fredericton, New Brunswick, Canada) was used to measure the thermal conductivity of the materials at room temperature. A four-point probe from Lucas Signatone Corporation (Gilroy, Calif.) was used to measure the electrical resistivity of the materials at room temperature. To measure the Seebeck coefficient of the materials at 200° C., temperature and voltage were measured at the same position across the material as a temperature gradient was applied.

Table 1 includes information about the amounts of different isoelectronic impurities and P type dopant that were included in different exemplary materials. FIGS. 10-13 graphically illustrate the results of measurements made on such materials, or calculations based on such measurements, as described in greater detail below. Sample 6 listed in Table 1 can be considered to be a “control” for samples 1, 2, 3, and 4 because it includes the same amount of boron (B) as do samples 1, 2, 3, and 4, but no isoelectronic impurities were added to it. Sample 7 listed in Table 1 can be considered to be a “control” for sample 5 because it includes the same amount of boron (B) as does sample 5, but no isoelectronic impurities were added to it.

TABLE 1

| Sample | Ge | Sn | B |
|---|---|---|---|
| No. | (at %) | (at %) | (1/cm³) |
| 1 | 1 | 0 | 2E20 |
| 2 | 0 | 0.1 | 2E20 |
| 3 | 1 | 0.1 | 2E20 |
| 4 | 1 | 0.5 | 2E20 |
| 5 | 1 | 0.5 | 7E20 |
| 6 | 0 | 0 | 2E20 |
| 7 | 0 | 0 | 7E20 |

FIG. 10 is a simplified diagram illustrating the measured electrical resistivity ρ (μΩm) of exemplary silicon-based thermoelectric materials including silicon and different amounts and types of isoelectronic impurities and a P type dopant as a function of amount of tin therein, according to certain embodiments of the present invention. It can be understood from FIG. 10 that the addition of tin in amounts between 0.1 and 1 atomic % improved electrical resistivity, and that the addition of germanium in amounts up to 1 atomic % in addition to the tin can provide further improvements to the electrical resistivity.

For example, as can be seen in FIG. 10, sample 1, which included 1 atomic % of Ge and 2E20/cm³ of B, was measured to have an electrical resistivity of 54 μΩm, which was higher than control sample 6, which included 2E20/cm³ of B, and was measured to have an electrical resistivity of 38 μΩm. Sample 2, which included 0.1 atomic % of Sn and 2E20/cm³ of B, was measured to have an electrical resistivity of 34 μΩm, which was lower than control sample 6, which included 2E20/cm³ of B, and was measured to have an electrical resistivity of 38 μΩm. Sample 3, which included 1 atomic % of Ge, 0.1 atomic % of Sn, and 2E20/cm³ of B, was measured to have an electrical resistivity of 31 μΩm, which was lower than control sample 6, which included 2E20/cm³ of B, and was measured to have an electrical resistivity of 38 μΩm. Sample 4, which included 1 atomic % of Ge, 0.5 atomic % of Sn, and 2E20/cm³ of B, was measured to have an electrical resistivity of 31 μΩm, which was lower than control sample 6, which included 2E20/cm³ of B, and was measured to have an electrical resistivity of 38 μΩm. Additionally, although not expressly illustrated in FIG. 10, sample 5, which included 1 atomic % of Ge, 0.5 atomic % of Sn and 7E20/cm³ of B, was measured to have an electrical resistivity of 10 μΩm, which was lower than control sample 7, which included 7E20/cm³ of B, and was measured to have an electrical resistivity of 16 μΩm.

Accordingly, it can be understood based on the data illustrated in FIG. 10 that sample 1, which included 1 atomic % Ge in addition to 2E20/cm³ of B, had an electrical resistivity that was about 142% of the electrical resistivity of control sample 6. Sample 2, which included 0.1 atomic % Sn in addition to 2E20/cm³ of B, had an electrical resistivity that was about 89.5% of the electrical resistivity of control sample 6. Sample 3, which included 1 atomic % of Ge, 0.1 atomic % of Sn, and 2E20/cm³ of B, had an electrical resistivity that was about 82% of the electrical resistivity of control sample 6. Sample 4, which included 1 atomic % of Ge, 0.5 atomic % of Sn, and 2E20/cm³ of B, had an electrical resistivity that was about 82% of the electrical resistivity of control sample 6. Additionally, although not expressly illustrated in FIG. 10, sample 5, which included 1 atomic % of Ge, 0.5 atomic % of Sn, and 7E20/cm³ of B, had an electrical resistivity that was about 62.5% of the electrical resistivity of control sample 7. Thus, it can be understood that many of the samples provided useful reductions to the electrical resistivity of the silicon.

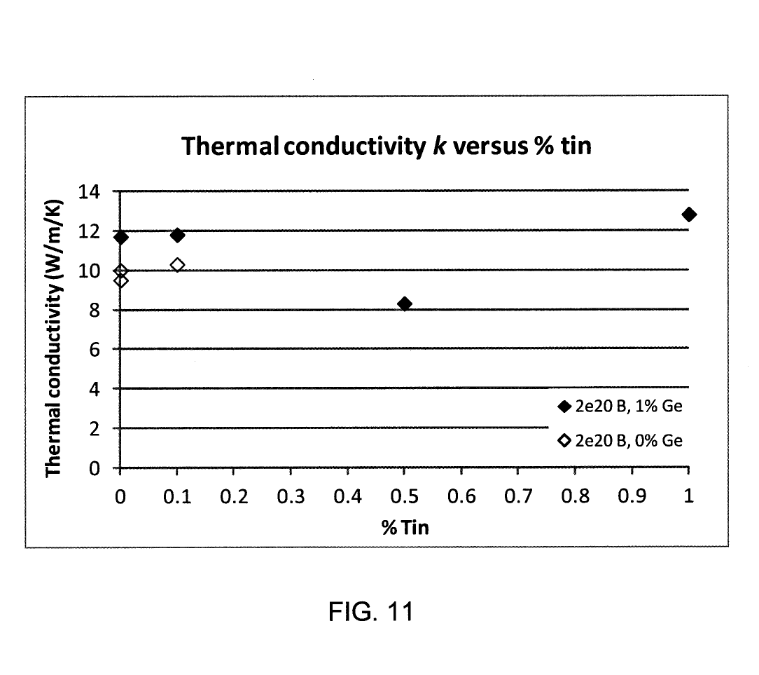

As another example, FIG. 11 is a simplified diagram illustrating the measured thermal conductivity k (W/mK) of exemplary silicon-based thermoelectric materials including silicon and different amounts and types of isoelectronic impurities and a P type dopant as a function of amount of tin therein, according to certain embodiments of the present invention. It can be understood from FIG. 10 that the addition of tin in amounts between 0.1 and 1 atomic % improved thermal conductivity, with amounts in the middle of this range (e.g., about 0.2 atomic % to 0.8 atomic %, e.g., about 0.5 atomic %) particularly improving the thermal conductivity, and that the addition of germanium in amounts up to 1 atomic % in addition to the tin can provide further improvements to the thermal conductivity.

For example, as can be seen in FIG. 11, sample 1, which included 1 atomic % of Ge and 2E20/cm³ of B, was measured to have a thermal conductivity of 11.7 W/mK, which was higher than control sample 6, which included 2E20/cm³ of B, and was measured to have a thermal conductivity of 9.5 W/mK. Sample 2, which included 0.1 atomic % of Sn and 2E20/cm³ of B, was measured to have a thermal conductivity of 10.3 W/mK, which was higher than control sample 6, which included 2E20/cm³ of B, and was measured to have a thermal conductivity of 9.5 W/mK. Sample 3, which included 1 atomic % of Ge, 0.1 atomic % of Sn, and 2E20/cm³ of B, was measured to have a thermal conductivity of 11.8 W/mK, which was higher than control sample 6, which included 2E20/cm³ of B, and was measured to have a thermal conductivity of 9.5 W/mK. Sample 4, which included 1 atomic % of Ge, 0.5 atomic % of Sn, and 2E20/cm³ of B, was measured to have a thermal conductivity of 8.3 W/mK, which was lower than control sample 6, which included 2E20/cm³ of B, and was measured to have a thermal conductivity of 9.5 W/mK. Although not expressly illustrated in FIG. 11, sample 5, which included 1 atomic % of Ge, 0.5 atomic % of Sn and 7E20/cm³ of B, was measured to have a thermal conductivity of 11.5 W/mK, which was lower than control sample 7, which included 7E20/cm³ of B, and was measured to have a thermal conductivity of 13.5 W/mK.

Accordingly, it can be understood based on the data illustrated in FIG. 11 that sample 1, which included 1 atomic % Ge in addition to 2E20/cm³ of B, had a thermal conductivity that was about 123% of the thermal conductivity of control sample 6. Sample 2, which included 0.1 atomic % Sn in addition to 2E20/cm³ of B, had a thermal conductivity that was about 108% of the thermal conductivity of control sample 6. Sample 3, which included 1 atomic % of Ge, 0.1 atomic % of Sn, and 2E20/cm³ of B, had a thermal conductivity that was about 102% of the thermal conductivity of control sample 6. Sample 4, which included 1 atomic % of Ge, 0.5 atomic % of Sn, and 2E20/cm³ of B, had a thermal conductivity that was about 87% of the thermal conductivity of control sample 6. Additionally, although not expressly illustrated in FIG. 11, sample 5, which included 1 atomic % of Ge, 0.5 atomic % of Sn, and 7E20/cm³ of B, had a thermal conductivity that was about 85% of the thermal conductivity of control sample 7. Thus, it can be understood that the amounts and types of isoelectronic impurities included in samples 4 and 5 provided a particularly useful reduction to the thermal conductivity of the silicon.

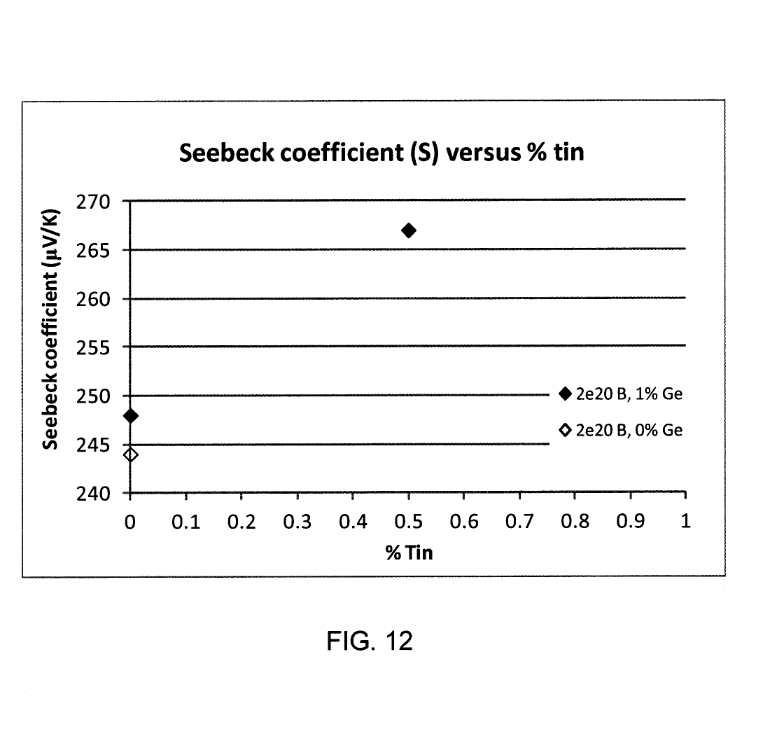

FIG. 12 is a simplified diagram illustrating the measured Seebeck coefficient S (μV/K) of exemplary silicon-based thermoelectric materials including silicon and different amounts and types of isoelectronic impurities and a P type dopant as a function of amount of tin therein, according to certain embodiments of the present invention. It can be understood from FIG. 12 that the addition of tin in amounts between 0.1 and 1 atomic % improved the Seebeck coefficient, and that the addition of germanium in amounts up to 1 atomic % can provide further improvements to the Seebeck coefficient.

For example, as can be seen in FIG. 12, sample 1, which included 1 atomic % of Ge and 2E20/cm³ of B, was measured to have an S value of 248 μV/K, which was higher than control sample 6, which included 2E20/cm³ of B, and was measured to have an S value of 244 μV/K. Sample 4, which included 1 atomic % of Ge, 0.5 atomic % of Sn, and 2E20/cm³ of B, was measured to have an S value of 267 μV/K, which was higher than control sample 6, which included 2E20/cm³ of B, and was measured to have an S value of 244 μV/K. Although not expressly illustrated in FIG. 12, sample 5, which included 1 atomic % of Ge, 0.5 atomic % of Sn and 7E20/cm³ of B, was measured to have an S value of 217 μV/K. The Seebeck coefficient S was not measured for samples 2, 3, or 7. Accordingly, it can be understood based on the data illustrated in FIG. 12 that sample 1, which included 1 atomic % Ge in addition to 2E20/cm³ of B, had an S value that was about 102% of the S value of control sample 6. Sample 4, which included 1 atomic % of Ge, 0.5 atomic % of Sn, and 2E20/cm³ of B, had an S value that was about 109% of the S value of control sample 6.

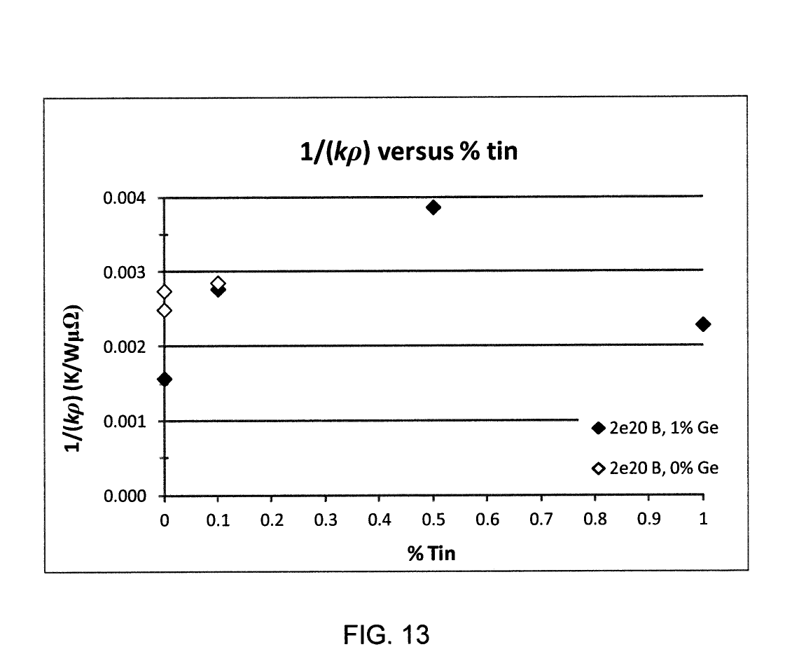

FIG. 13 is a simplified diagram illustrating the reciprocal 1/kρ (K(WμΩ)) of the product kρ of the measured thermal conductivity k and electrical resistivity ρ of exemplary silicon-based thermoelectric materials including silicon and different amounts and types of isoelectronic impurities and a P type dopant as a function of amount of tin therein, according to certain embodiments of the present invention. From the solid points illustrated in FIG. 13, it can be understood that the 1/kρ value improves markedly when 0.1 atomic % Sn is added to a Si sample with 2e20 B and 1 atomic % Ge. The 1/kρ value can be seen to improve further if 0.5 atomic % Sn is added, but then gets worse if 1 atomic % Sn is added. From the solid and white points at 0 atomic % Sn illustrated in FIG. 13, it can be understood that adding 1 atomic % Ge with 0 atomic % Sn can make 1/kρ worse than 0 atomic % Ge with 0 atomic % Sn. From the open points illustrated in FIG. 13, it can be understood that adding 1 atomic % Ge with 0.1 atomic % Sn can improve the result over 0 atomic % Ge, 0 atomic % Sn. Such a result can be considered to be surprising, given that adding 1 atomic % Ge with 0 atomic % Sn can make 1/kρ worse than 0 atomic % Ge with 0 atomic % Sn. Accordingly, without wishing to be bound by any theory, it is believed that these results with addition of Sn (in the presence of Ge, e.g., 1 atomic % Ge) clearly show improvement in figure of merit ZT if the right amount is added, as well as a nonlinear, synergistic effect resulting from disposing certain amounts of two different isoelectronic impurities within the silicon. For example, a material that includes 1 atomic % Ge and 0.01 atomic % Sn to 1 atomic % Sn can exhibit improved figure of merit ZT. Or, for example, a material that includes 1 atomic % Ge and 0.1 atomic % Sn to 1 atomic % Sn can exhibit improved figure of merit ZT. Or, for example, a material that includes 1 atomic % Ge and 0.1 atomic % Sn to 0.9 atomic % Sn can exhibit improved figure of merit ZT. Or, for example, a material that includes 1 atomic % Ge and 0.2 atomic % Sn to 0.8 atomic % Sn can exhibit improved figure of merit ZT. Or, for example, a material that includes 1 atomic % Ge and 0.3 atomic % Sn to 0.7 atomic % Sn can exhibit improved figure of merit ZT. Or, for example, a material that includes 1 atomic % Ge and 0.4 atomic % Sn to 0.6 atomic % Sn can exhibit improved figure of merit ZT. Or, for example, a material that includes 1 atomic % Ge and about 0.5 atomic % Sn can exhibit improved figure of merit ZT.

Additionally, it should be appreciated that although the present exemplary materials included either 0 atomic % Ge or 1 atomic % Ge in combination with varying amounts of Sn, it can be expected that materials including other amounts of Ge or one or more other isoelectronic impurities, or both, can exhibit improved figure of merit ZT. For example, a material that includes 0.01 atomic % to 2 atomic % Ge and 0.01 atomic % Sn to 1 atomic % each of one or more isoelectronic impurities selected from C, Sn, and Pb can exhibit improved figure of merit ZT. Or, for example, a material that includes 0.01 atomic % to 2 atomic % Ge and 0.1 atomic % Sn to 1 atomic % each of one or more isoelectronic impurities selected from C, Sn, and Pb can exhibit improved figure of merit ZT. Or, for example, a material that includes 0.01 atomic % to 2 atomic % Ge and 0.1 atomic % to 0.9 atomic % each of one or more isoelectronic impurities selected from C, Sn, and Pb can exhibit improved figure of merit ZT. Or, for example, a material that includes 0.01 atomic % to 2 atomic % Ge and 0.2 atomic % to 0.8 atomic % each of one or more isoelectronic impurities selected from C, Sn, and Pb can exhibit improved figure of merit ZT. Or, for example, a material that includes 0.01 atomic % to 2 atomic % Ge and 0.3 atomic % to 0.7 atomic % each of one or more isoelectronic impurities selected from C, Sn, and Pb can exhibit improved figure of merit ZT. Or, for example, a material that includes 0.01 atomic % to 2 atomic % Ge and 0.4 atomic % to 0.6 atomic % each of one or more isoelectronic impurities selected from C, Sn, and Pb can exhibit improved figure of merit ZT. Or, for example, a material that includes 0.01 atomic % to 2 atomic % Ge and about 0.5 atomic % each of one or more isoelectronic impurities selected from C, Sn, and Pb can exhibit improved figure of merit ZT. In other embodiments, a material that includes 0.01 atomic % to 2 atomic % Ge and 0.01 atomic % to 2 atomic % each of one or more isoelectronic impurities selected from C, Sn, and Pb can exhibit improved figure of merit ZT. For example, a material that includes 0.01 atomic % to 2 atomic % Ge and 1 atomic % to 2 atomic % each of one or more isoelectronic impurities selected from C, Sn, and Pb can exhibit improved figure of merit ZT. Each material mentioned in the present paragraph can, for example, include 0.01 atomic % to 1 atomic % Ge, or 0.1 atomic % to 0.9 atomic % Ge, or 0.2 atomic % to 0.8 atomic % Ge, or 0.3 atomic % to 0.7 atomic % Ge, or 0.4 atomic % to 0.6 atomic % Ge, or about 0.5 atomic % Ge.

Other materials also were prepared and their thermal conductivities of other samples also were measured, and are summarized below in Table 2. The samples were prepared using a diffusion apparatus analogous to that illustrated in FIG. 9. More specifically, 1.0 gram of tin shot (99.8%, Sigma Aldrich) was placed in a crucible below a porous (fritted) glass disc. 2.5 grams of silicon nanowires that were N doped with phosphorous were placed on top of the fritted disc and a lid was placed on the crucible. The loaded crucible was placed in a sintering furnace and the temperature was increased to 1100° C. and held at that temperature for 48 hours. 40% of the maximum N₂ flow rate for the furnace (e.g., 40% of 100 standard cm³/min) was flowing over the samples. The diffusion constant D of tin in silicon is approximately 1E-15 cm²/s, based upon which an approximately 30 hour diffusion time can be expected to provide an approximately 200 nm diffusion depth. A first control pellet was analogously prepared in the diffusion furnace, but without diffusing tin into the pellet. A second control pellet was not heated in the diffusion furnace. It was observed that white residue formed around the lids of the crucibles during the furnace runs for the first control pellet and the pellet including tin. The residue was analyzed using energy-dispersive X-ray spectroscopy (EDX) and it was determined the residue did not contain Sn. Scanning electron microscopy (SEM) of the residue showed nanostructured filaments. Without wishing to be bound by any theory, it was believed that the residue may have been SiO₂.

The thermal conductivity and electrical resistivity of the three samples was measured analogously as described above. Additionally, the relative densities of the samples were measured by measuring the mass, thickness, and diameter of the resulting pellet and comparing the ratio of mass/volume to that of bulk silicon, 2.33 g/cm³. The results can be interpreted as demonstrating that including an isoelectronic impurity such as tin can reduce the thermal conductivity of the sintered nanowire independently of other effects in the process. For example, from Table 2, it can be seen that the thermal conductivity of the sample that included tin was measured to be approximately 5.5-6 W/m/K, which was approximately 46-60% of the thermal conductivity of 9.1-13 W/m/K of the second control sample, and approximately 73-75% of the thermal conductivity of 7.5-8 W/m/K of the first control sample. Accordingly, it can be seen that adding tin provided a significantly lower thermal conductivity than otherwise similar samples. Without wishing to be bound by any theory, it was believed that the Sn impurities may have inhibited sintering of the Si nanowire based pellets.

TABLE 2

| | Relative | Thermal |
|---|---|---|
| | density | conductivity |
| Sample preparation of Si nanowires | [%] | [W/m/K] |
| No Sn doping, no heating | 66 | 9.1-13 |
| No Sn doping, heat to 1100 C. in N₂ environment | 56 | 7.5-8 |
| Sn doping, heat to 1100 C. in N₂ environment | 55 | 5.5-6 |

Accordingly, as provided herein, introduction of isoelectronic impurities, e.g., relatively heavy or light atoms (or a mixture thereof) as compared to silicon, into a material can be applied for reducing the thermal conductivity. By introducing at least one or more isoelectronic impurities into a Si material, the thermal conductivity can be reduced from its bulk value without compromising the electronic structure that renders Si a promising thermoelectric material which can be provided, for example, nanoribbons, nanocrystals, nanowires, inverse opal, low dimension silicon material (thin film, nanostructured silicon powder, mesoporous particles, and the like), raw silicon material, wafer, and sintered structures in at least partially bulk form. Electronic N or P type dopants, e.g., from group III or group V elements, can also be introduced to further improve or optimize the Seebeck coefficient and electrical resistivity of the material for being used as base material, e.g., for forming either N-type or P-type thermoelectric legs.

For example, relatively heavy atoms can be incorporated into a thermoelectric material so as to reduce the material's thermal conductivity. Without wishing to be bound by any theory, relatively heavy, relatively weakly bonded atoms are believed to be less efficient transporters of heat. When introduced into the Si material, such atoms can serve as phonon scattering sites that impede heat transfer. Without wishing to be bound by any theory, it is believed that certain amounts of certain isoelectronic elements can reduce the thermal conductivity of silicon with relatively low, or minimal, impact on the Seebeck coefficient and electrical conductivity. Any combination of isoelectronic atoms could be used, including group IV isotopes. A particularly simple isoelectronic element to incorporate is tin, which has relatively high solid solubility in silicon, relatively high diffusivity in silicon, similar bonding structure as Si, and is ˜4.3× more massive than Si. In conjunction with standard electronic dopants (P or B), Sn impurities alone, or in combination with other isoelectronic impurities such as Ge, can offer significant improvements in the thermoelectric figure of merit ZT of silicon-based thermoelectric materials. However, it should be understood that any suitable combination of one or more of C, Ge, Sn, and Pb can be included in silicon so as to provide a material having enhanced thermoelectric properties.

According to another embodiment, a thermoelectric material includes silicon; and one or more isoelectronic impurity atoms selected from the group consisting of carbon, tin, and lead disposed within the silicon in an amount sufficient to scatter thermal phonons propagating through the silicon and below a saturation limit of the one or more isoelectronic impurity atoms in the silicon. In one example, the thermoelectric material is described above with reference to FIGS. 1B and/or 1C. In another example, the thermoelectric material is made according to at least FIG. 7, FIG. 8A, FIG. 8B, FIG. 8C, FIG. 8D, FIG. 8E, FIG. 8F, and/or FIG. 9.

In one example, the thermoelectric material includes germanium atoms disposed within the silicon in an amount sufficient to scatter thermal phonons propagating through the silicon and below a saturation limit of germanium in the silicon. In one example, the thermoelectric material is described above with reference to FIG. 1C. In another example, the thermoelectric material is made according to at least FIG. 7, FIG. 8A, FIG. 8B, FIG. 8C, FIG. 8D, FIG. 8E, FIG. 8F, and/or FIG. 9.

In another example, each of the one or more isoelectronic impurity atoms and the germanium atoms independently substitutes for a silicon atom or is disposed within an interstice of the silicon. In another example, the silicon, the one or more isoelectronic impurity atoms, and the germanium atoms define a single phase of the thermoelectric material. In another example, the thermoelectric material further includes an N or P type dopant disposed within the silicon. In another example, the thermoelectric material consists essentially of the silicon, the one or more isoelectronic impurity atoms, the germanium atoms, and the N or P type dopant. In another example, the amount of the germanium atoms is approximately 0.001 atomic % to approximately 2 atomic %, and the amount of each of the one or more isoelectronic impurity atoms is approximately 0.001 atomic % to approximately 2 atomic %. In another example, the amount of each of the one or more isoelectronic impurity atoms is approximately 0.001 atomic % to approximately 2 atomic %. In another example, the one or more isoelectronic impurity atoms include tin and carbon. In another example, the one or more isoelectronic impurity atoms include tin and lead. In another example, the one or more isoelectronic impurity atoms include carbon and the material further includes germanium. In another example, the one or more isoelectronic impurity atoms include lead and the material further includes germanium.

In another example, a nanocrystal, nanowire, or nanoribbon includes a thermoelectric material includes silicon; and one or more isoelectronic impurity atoms disposed within the silicon in an amount sufficient to scatter thermal phonons propagating through the silicon and below a saturation limit of the one or more isoelectronic impurity atoms in the silicon. In one example, the thermoelectric material is described above with reference to FIGS. 1B and/or 1C. In another example, the thermoelectric material is made according to at least FIG. 7, FIG. 8A, FIG. 8B, FIG. 8C, FIG. 8D, FIG. 8E, FIG. 8F, and/or FIG. 9.

According to another embodiment, a device for thermoelectric conversion includes a first electrode; a second electrode; and a thermoelectric material disposed between the first electrode and the second electrode. The thermoelectric material includes silicon; and one or more isoelectronic impurity atoms selected from the group consisting of carbon, tin, and lead disposed within the silicon in an amount sufficient to scatter thermal phonons propagating through the silicon and below a saturation limit of the one or more isoelectronic impurity atoms in the silicon. In one example, the device is described above with reference to FIG. 2A, FIG. 2B, and/or FIG. 2C. In another example, the thermoelectric material is described above with reference to FIGS. 1B and/or 1C. In another example, the thermoelectric material is made according to at least FIG. 7, FIG. 8A, FIG. 8B, FIG. 8C, FIG. 8D, FIG. 8E, FIG. 8F, and/or FIG. 9.

In another example, the thermoelectric material further includes germanium atoms disposed within the silicon in an amount sufficient to scatter thermal phonons propagating through the silicon and below a saturation limit of germanium in the silicon. In one example, the thermoelectric material is described above with reference to FIG. 1C. In another example, the thermoelectric material is made according to at least FIG. 7, FIG. 8A, FIG. 8B, FIG. 8C, FIG. 8D, FIG. 8E, FIG. 8F, and/or FIG. 9.

In another example, each of the one or more isoelectronic impurity atoms and the germanium atoms independently substitutes for a silicon atom in the silicon or is disposed within an interstice of the silicon. In another example, the silicon, the one or more isoelectronic impurity atoms, and the germanium atoms define a single phase of the thermoelectric material. In another example, the thermoelectric material further includes an N or P type dopant disposed within the silicon. In another example, the thermoelectric material consists essentially of the silicon, the one or more isoelectronic impurity atoms, the germanium atoms, and the N or P type dopant. In another example, the amount of the germanium atoms is approximately 0.001 atomic % to approximately 2 atomic %, and the amount of each of the one or more isoelectronic impurity atoms is approximately 0.001 atomic % to approximately 2 atomic %. In another example, the amount of each of the one or more isoelectronic impurity atoms is approximately 0.001 atomic % to approximately 2 atomic %. In another example, the device is configured to generate an electric current flowing between the first electrode and the second electrode through the thermoelectric material based on the first and second electrodes being at different temperatures than one another. In another example, the one or more isoelectronic impurity atoms include tin and carbon. In another example, the one or more isoelectronic impurity atoms include tin and lead. In another example, the one or more isoelectronic impurity atoms include carbon and the material further includes germanium. In another example, the one or more isoelectronic impurity atoms include lead and the material further includes germanium. In yet another example, the one or more isoelectronic impurity atoms include tin and the material further includes germanium.

According to yet another embodiment, a method of making a thermoelectric material includes providing silicon; and disposing one or more isoelectronic impurity atoms selected from the group consisting of carbon, tin, and lead within the silicon in an amount sufficient to scatter thermal phonons propagating through the silicon and below a saturation limit of the one or more isoelectronic impurity atoms in the silicon. In one example, the thermoelectric material is made according to at least FIG. 7, FIG. 8A, FIG. 8B, FIG. 8C, FIG. 8D, FIG. 8E, FIG. 8F, and/or FIG. 9. In another example, the thermoelectric material is described above with reference to FIGS. 1B and/or 1C.

In another example, the method includes disposing germanium atoms within the silicon in an amount sufficient to scatter thermal phonons propagating through the silicon and below a saturation limit of germanium in the silicon. In one example, the thermoelectric material is made according to at least FIG. 7, FIG. 8A, FIG. 8B, FIG. 8C, FIG. 8D, FIG. 8E, FIG. 8F, and/or FIG. 9. In another example, the thermoelectric material is described above with reference to FIG. 1C.

In yet another example, the silicon, the one or more isoelectronic impurity atoms, and the germanium atoms define a single phase of the thermoelectric material. In another example, the method includes independently substituting each of the one or more isoelectronic impurity atoms and the germanium atoms for a silicon atom in the silicon or disposing that isoelectronic impurity atom or germanium atom within an interstice of the silicon. In another example, the silicon, the one or more isoelectronic impurity atoms, and the germanium atoms define a single phase of the thermoelectric material. In another example, the method further includes disposing an N or P type dopant within the silicon. In another example, the thermoelectric material consists essentially of the silicon, the one or more isoelectronic impurity atoms, the germanium atoms, and the N or P type dopant. In another example, the amount of the germanium atoms is approximately 0.001 atomic % to approximately 2 atomic %, and the amount of each of the one or more isoelectronic impurity atoms is approximately 0.001 atomic % to approximately 2 atomic %. In another example, the amount of each of the one or more isoelectronic impurity atoms is approximately 0.001 atomic % to approximately 2 atomic %. In yet another example, disposing the one or more isoelectronic impurity atoms within the silicon includes disposing the silicon within a diffusion furnace; and diffusing the one or more isoelectronic impurity atoms into the silicon within the diffusion furnace. In yet another example, disposing the one or more isoelectronic impurity atoms within the silicon includes obtaining a powdered mixture of silicon and the one or more isoelectronic impurity; and sintering the powdered mixture to form the silicon having the one or more isoelectronic impurity atoms disposed therein. In yet another example, disposing the one or more isoelectronic impurity atoms within the silicon includes obtaining a melt of silicon and the one or more isoelectronic impurity; and solidifying the melt to form the silicon having the one or more isoelectronic impurity atoms disposed therein. In yet another example, the one or more isoelectronic impurity atoms include tin and carbon. In another example, the one or more isoelectronic impurity atoms include tin and lead. In another example, the one or more isoelectronic impurity atoms include carbon and the material further includes germanium. In another example, the one or more isoelectronic impurity atoms include lead and the material further includes germanium. In yet another example, the one or more isoelectronic impurity atoms include tin and the material further includes germanium.

According to yet another embodiment, a method of making a thermoelectric device includes providing a thermoelectric material, and disposing the thermoelectric material between a first electrode and a second electrode. The thermoelectric material includes silicon; and one or more isoelectronic impurity atoms selected from the group consisting of carbon, tin, and lead disposed within the silicon in an amount sufficient to scatter thermal phonons propagating through the silicon and below a saturation limit of the one or more isoelectronic impurity atoms in the silicon. In one example, the device is made according to at least FIG. 6. In another example, the device is described above with reference to FIG. 2A, FIG. 2B, and/or FIG. 2C. In another example, the thermoelectric material is made according to at least FIG. 7, FIG. 8A, FIG. 8B, FIG. 8C, FIG. 8D, FIG. 8E, FIG. 8F, and/or FIG. 9. In another example, the thermoelectric material is described above with reference to FIGS. 1B and/or 1C.

In another example, the thermoelectric material further includes germanium atoms disposed within the silicon in an amount sufficient to scatter thermal phonons propagating through the silicon and below a saturation limit of germanium in the silicon. In one example, the thermoelectric material is made according to at least FIG. 7, FIG. 8A, FIG. 8B, FIG. 8C, FIG. 8D, FIG. 8E, FIG. 8F, and/or FIG. 9. In another example, the thermoelectric material is described above with reference to FIG. 1C.

In yet another example, the silicon, the one or more isoelectronic impurity atoms, and the germanium atoms define a single phase of the thermoelectric material. In another example, each of the one or more isoelectronic impurity atoms and the germanium atoms independently substitutes for a silicon atom in the silicon or is disposed within an interstice of the silicon. In another example, the silicon, the one or more isoelectronic impurity atoms, and the germanium atoms define a single phase of the thermoelectric material. In another example, the thermoelectric material further includes an N or P type dopant disposed within the silicon. In another example, the thermoelectric material consists essentially of the silicon, the one or more isoelectronic impurity atoms, the germanium atoms, and the N or P type dopant. In another example, the amount of the germanium atoms is approximately 0.001 atomic % to approximately 2 atomic %, and the amount of each of the one or more isoelectronic impurity atoms is approximately 0.001 atomic % to approximately 2 atomic %. In another example, the amount of each of the one or more isoelectronic impurity atoms is approximately 0.001 atomic % to approximately 2 atomic %. In another example, the one or more isoelectronic impurity atoms include tin and carbon. In another example, the one or more isoelectronic impurity atoms include tin and lead. In another example, the one or more isoelectronic impurity atoms include carbon and the material further includes germanium. In another example, the one or more isoelectronic impurity atoms include lead and the material further includes germanium. In yet another example, the one or more isoelectronic impurity atoms include tin and the material further includes germanium.

According to yet another embodiment, a method of using a thermoelectric device includes providing a thermoelectric device; and generating an electric current flowing between the first electrode and the second electrode through the thermoelectric material based on the first and second electrodes being at different temperatures than one another. The thermoelectric material includes silicon; and one or more isoelectronic impurity atoms selected from the group consisting of carbon, tin, and lead disposed within the silicon in an amount sufficient to scatter thermal phonons propagating through the silicon and below a saturation limit of the one or more isoelectronic impurity atoms in the silicon. In one example, the device is made and used according to at least FIG. 6. In another example, the device is described above with reference to FIG. 2A and/or FIG. 2B. In another example, the thermoelectric material is made according to at least FIG. 7, FIG. 8A, FIG. 8B, FIG. 8C, FIG. 8D, FIG. 8E, FIG. 8F, and/or FIG. 9. In another example, the thermoelectric material is described above with reference to FIGS. 1B and/or 1C.

According to still another embodiment, a method of using a thermoelectric device includes providing a thermoelectric device; and pumping heat from the first electrode to the second electrode through the thermoelectric material responsive to an electrical current. The thermoelectric material includes silicon; and one or more isoelectronic impurity atoms selected from the group consisting of carbon, tin, and lead disposed within the silicon in an amount sufficient to scatter thermal phonons propagating through the silicon and below a saturation limit of the one or more isoelectronic impurity atoms in the silicon. In one example, the device is made and used according to at least FIG. 6. In another example, the device is described above with reference to FIG. 2C. In another example, the thermoelectric material is made according to at least FIG. 7, FIG. 8A, FIG. 8B, FIG. 8C, FIG. 8D, FIG. 8E, FIG. 8F, and/or FIG. 9. In another example, the thermoelectric material is described above with reference to FIGS. 1B and/or 1C.

Although specific embodiments of the present invention have been described, it will be understood by those of skill in the art that there are other embodiments that are equivalent to the described embodiments. For example, various embodiments and/or examples of the present invention can be combined. Accordingly, it is to be understood that the invention is not to be limited by the specific illustrated embodiments, but only by the scope of the appended claims.

1. A thermoelectric material, comprising:
silicon; and
one or more isoelectronic impurity atoms selected from the group consisting of carbon, tin, and lead disposed within the silicon in an amount sufficient to scatter thermal phonons propagating through the silicon and below a saturation limit of the one or more isoelectronic impurity atoms in the silicon.

2. The thermoelectric material of claim 1, further comprising germanium atoms disposed within the silicon in an amount sufficient to scatter thermal phonons propagating through the silicon and below a saturation limit of germanium in the silicon.

3. The thermoelectric material of claim 2, wherein each of the one or more isoelectronic impurity atoms and the germanium atoms independently substitutes for a silicon atom or is disposed within an interstice of the silicon.

4. The thermoelectric material of claim 3, wherein the silicon, the one or more isoelectronic impurity atoms, and the germanium atoms define a single phase of the thermoelectric material.

5. The thermoelectric material of claim 2, further comprising an N or P type dopant disposed within the silicon.

6. The thermoelectric material of claim 5, consisting essentially of the silicon, the one or more isoelectronic impurity atoms, the germanium atoms, and the N or P type dopant.

7. The thermoelectric material of claim 2, wherein the amount of the germanium atoms is approximately 0.001 atomic % to approximately 2 atomic %, and wherein the amount of each of the one or more isoelectronic impurity atoms is approximately 0.001 atomic % to approximately 2 atomic %.

8. The thermoelectric material of claim 1, wherein the amount of each of the one or more isoelectronic impurity atoms is approximately 0.001 atomic % to approximately 2 atomic %.

9. A nanocrystal, nanowire, or nanoribbon comprising the thermoelectric material of claim 1.

10. The thermoelectric material of claim 1, wherein the one or more isoelectronic impurity atoms include tin and carbon.

11. The thermoelectric material of claim 1, wherein the one or more isoelectronic impurity atoms include tin and lead.

12. The thermoelectric material of claim 1, wherein the one or more isoelectronic impurity atoms include carbon and the material further comprises germanium.

13. The thermoelectric material of claim 1, wherein the one or more isoelectronic impurity atoms include lead and the material further comprises germanium.

14. A device for thermoelectric conversion, the device comprising:
a first electrode;
a second electrode;
a thermoelectric material disposed between the first electrode and the second electrode, the thermoelectric material comprising:
silicon; and
one or more isoelectronic impurity atoms selected from the group consisting of carbon, tin, and lead disposed within the silicon in an amount sufficient to scatter thermal phonons propagating through the silicon and below a saturation limit of the one or more isoelectronic impurity atoms in the silicon.

15-21. (canceled)

22. The device of claim 14, being configured to generate an electric current flowing between the first electrode and the second electrode through the thermoelectric material based on the first and second electrodes being at different temperatures than one another.

23-26. (canceled)

27. A method of making a thermoelectric material, the method comprising:
providing silicon; and
disposing one or more isoelectronic impurity atoms within the silicon in an amount sufficient to scatter thermal phonons propagating through the silicon and below a saturation limit of the one or more isoelectronic impurity atoms in the silicon.

28-35. (canceled)

36. The method of claim 27, wherein disposing the one or more isoelectronic impurity atoms within the silicon comprises:
disposing the silicon within a diffusion furnace; and
diffusing the one or more isoelectronic impurity atoms into the silicon within the diffusion furnace.

37. The method of claim 27, wherein disposing the one or more isoelectronic impurity atoms within the silicon comprises:
obtaining a powdered mixture of silicon and the one or more isoelectronic impurity atoms; and
sintering the powdered mixture to form the silicon having the one or more isoelectronic impurity atoms disposed therein.

38. The method of claim 27, wherein disposing the one or more isoelectronic impurity atoms within the silicon comprises:
obtaining a melt of silicon and the one or more isoelectronic impurity atoms; and
solidifying the melt to form the silicon having the one or more isoelectronic impurity atoms disposed therein.

39-42. (canceled)

43. A method of making a thermoelectric device, the method comprising:
providing a thermoelectric material comprising:
silicon; and
one or more isoelectronic impurity atoms selected from the group consisting of carbon, tin, and lead disposed within the silicon in an amount sufficient to scatter thermal phonons propagating through the silicon and below a saturation limit of the one or more isoelectronic impurity atoms in the silicon; and
disposing the thermoelectric material between a first electrode and a second electrode.

44-55. (canceled)

56. A method of using a thermoelectric device, the method comprising:
providing a thermoelectric device using the method of claim 43; and
generating an electric current flowing between the first electrode and the second electrode through the thermoelectric material based on the first and second electrodes being at different temperatures than one another.

57. A method of using a thermoelectric device, the method comprising:
providing a thermoelectric device using the method of claim 43; and
pumping heat from the first electrode to the second electrode through the thermoelectric material responsive to an electrical current.

58. The thermoelectric material of claim 1, wherein the one or more isoelectronic impurity atoms include tin and the material further comprises germanium.

59. The device of claim 14, wherein the one or more isoelectronic impurity atoms include carbon and the material further comprises germanium.

60. The method of claim 27, wherein the one or more isoelectronic impurity atoms include carbon and the material further comprises germanium.

61. The method of claim 43, wherein the one or more isoelectronic impurity atoms include carbon and the material further comprises germanium.
